(19) United States
(12) Patent Application Publication
(10) Pub. No.: US 2026/0013189 A1
(43) Pub. Date: Jan. 8, 2026

(54) SEMICONDUCTOR DEVICE AND METHOD OF MANUFACTURING SEMICONDUCTOR DEVICE

(71) Applicant: Mitsubishi Electric Corporation, Tokyo (JP)

(72) Inventors: Kazuya ISHIBASHI, Tokyo (JP); Kazunori KANADA, Fukuoka (JP); Naoki SHIKAMA, Tokyo (JP); Yasuhiro KAGAWA, Tokyo (JP); Hiroki NIWA, Tokyo (JP); Katsutoshi SUGAWARA, Tokyo (JP)

(73) Assignee: Mitsubishi Electric Corporation, Tokyo (JP)

(21) Appl. No.: 19/194,712

(22) Filed: Apr. 30, 2025

(30) Foreign Application Priority Data
Jul. 8, 2024 (JP) 2024-109491

(51) Int. Cl. H10D 62/60; H01L 21/265; H10D 30/66

(52) U.S. Cl. CPC H10D 62/60; H01L 21/26586; H10D 30/665

(57) ABSTRACT

A semiconductor device includes: a first semiconductor layer that has a first surface and a second surface facing the first surface in a first direction, contains recombination centers, and has a first conductivity type; and a second semiconductor layer that is adjacent to the second surface and has a second conductivity type which is opposite to the first conductivity type. Local maxima appear in a distribution of a concentration of the recombination centers in the first direction at at least one position between the first surface and the second surface and away from either of the first surface and the second surface.

### BACKGROUND

### Technical Field

The present disclosure relates to a semiconductor device and a method of manufacturing the semiconductor device.

### Description of the Background Art

In a semiconductor device, it is preferable to suppress expansion of stacking faults. For example, stacking faults expand due to application of a current to the semiconductor device. Stacking faults start from, for example, a basal plane dislocation. For example, expansion of stacking faults in a substrate of a semiconductor device (hereinafter, also referred to as “silicon carbide semiconductor device”) in which silicon carbide is adopted as a semiconductor material is known. The expansion of stacking faults causes an increase in a forward voltage of the semiconductor device. An increase in the forward voltage leads to deterioration in reliability of the semiconductor device.

An example of a technique for suppressing expansion of stacking faults due to application of a current is disclosed in Japanese Patent Application Laid-Open No. 2022-17550. Japanese Patent Application Laid-Open No. 2022-17550 discloses a silicon carbide semiconductor device in which a substrate, a boundary layer, and a drift layer having the same conductivity type are stacked in this order. Both the boundary layer and the drift layer are formed by epitaxial growth. The boundary layer has a lower impurity concentration than the substrate, and the drift layer has a lower impurity concentration than the boundary layer.

Japanese Patent Application Laid-Open No. 2022-17550 illustrates a case where the substrate is a single crystal substrate and includes a basal plane dislocation, for example. According to Japanese Patent Application Laid-Open No. 2022-17550, when there is a defect in the crystal of the substrate, the basal plane dislocation existing in the substrate moves by recombination energy, and the stacking faults sandwiched between two basal plane dislocations expand.

The boundary layer is provided to prevent crystal defects of the substrate from being transmitted to the drift layer. Protons implanted in the vicinity of an interface between the substrate and the boundary layer act as lifetime killers and decrease the hole density of the interface. As a result, recombination between holes and electrons (hereinafter simply referred to as “recombination”) is reduced, and the growth of crystal defects is suppressed.

However, stacking faults exist not only in the substrate but also in the epitaxial layer. The application of the current to the semiconductor device also expands the stacking faults which are present in the epitaxial layer. It is presumed that Japanese Patent Application Laid-Open No. 2022-17550 is a technique for suppressing growth of basal plane dislocations included in a substrate into stacking faults. It is unclear whether the expansion of the stacking faults inherent in the semiconductor layer provided on the substrate is suppressed by protons implanted at the boundary between the semiconductor layer and the substrate.

### SUMMARY

An object of the present disclosure is to suppress expansion of stacking faults inherent in a semiconductor layer.

The semiconductor device according to the present disclosure includes a first semiconductor layer of a first conductivity type, and a second semiconductor layer of a second conductivity type which is opposite to the first conductivity type. The first semiconductor layer has a first surface and a second surface facing the first surface in a first direction, and contains recombination centers. The second semiconductor layer is adjacent to the second surface. Local maxima appear in a distribution of a concentration of the recombination centers in the first direction at at least one position between the first surface and the second surface and away from either of the first surface and the second surface. According to the semiconductor device of the present disclosure, the expansion

of the stacking faults inherent in the semiconductor layer is suppressed.

These and other objects, features, aspects and advantages of the present disclosure will become more apparent from the following detailed description of the present disclosure when taken in conjunction with the accompanying drawings.

### BRIEF DESCRIPTION OF THE DRAWINGS

FIGS. 1 and 2 are cross-sectional views schematically illustrating a semiconductor device according to a first preferred embodiment of the present disclosure, respectively;

FIG. 3 is a cross-sectional view schematically illustrating the semiconductor device according to the first preferred embodiment of the present disclosure and a concentration distribution of recombination centers;

FIG. 4 is a cross-sectional view schematically illustrating a semiconductor device according to a second preferred embodiment of the present disclosure;

FIG. 5 is a cross-sectional view schematically illustrating a semiconductor device according to a third preferred embodiment of the present disclosure;

FIG. 6 is a cross-sectional view schematically illustrating a semiconductor device according to a fourth preferred embodiment of the present disclosure;

FIG. 7 is a cross-sectional view schematically illustrating a semiconductor device according to a fifth preferred embodiment of the present disclosure;

FIGS. 8 and 9 are cross-sectional views schematically illustrating a semiconductor device according to a sixth preferred embodiment of the present disclosure, respectively;

FIGS. 10 to 13 are cross-sectional views schematically illustrating a semiconductor device according to a seventh preferred embodiment of the present disclosure, respectively;

FIGS. 14 to 16 are cross-sectional views schematically illustrating a semiconductor device according to an eighth preferred embodiment of the present disclosure, respectively;

FIG. 17 is a plan view schematically illustrating a wafer and dies according to a ninth embodiment of the present disclosure;

FIG. 18 is a plan view schematically illustrating one of the dies;

FIG. 19 is a plan view schematically illustrating a wafer and dies according to the ninth embodiment of the present disclosure;

FIG. 20 is a plan view schematically illustrating one of the dies;

FIGS. 21 and 22 are cross-sectional views schematically illustrating a semiconductor device according to the ninth preferred embodiment of the present disclosure, respectively;

FIG. 23 is a cross-sectional view schematically illustrating modification of a termination region;

FIG. 24 is a cross-sectional view schematically illustrating a first example of a tenth embodiment;

FIG. 25 is a cross-sectional view schematically illustrating a second example of the tenth embodiment; and

FIG. 26 is a flowchart illustrating an outline of steps of manufacturing various semiconductor devices according to the present disclosure.

### DESCRIPTION OF THE PREFERRED EMBODIMENTS

Preferred embodiments will be described with reference to the accompanying drawings. The drawings are schematically illustrated. The correlation between the sizes and positions of the images respectively illustrated in the different drawings is not necessarily accurately described, and may be appropriately changed. The same reference numerals are adopted for similar components, and their names and functions are also similar. Therefore, redundant detailed description may be omitted.

In the following description, terms may be used that mean specific positions and directions, such as “up”, “down”, “side”, “bottom”, “front” or “back”. These terms are used for convenience to facilitate understanding of the contents of the preferred embodiments. Therefore, terms meaning these positions and directions do not necessarily coincide with the positions and directions at the time of actual implementation. When directions are indicated in the present disclosure, a right-handed XYZ coordinate system may be utilized.

In the preferred embodiments according to the present disclosure, each of symbols “n” and “p” indicates a conductivity type of a semiconductor. In the present disclosure, the n-type conductivity type can be regarded as a first conductivity type, and the p-type conductivity type can be regarded as a second conductivity type. The p-type conductivity type may also be adopted as the first conductivity type, and the n-type conductivity type may also be adopted as the second conductivity type.

The term “defect” used in the present disclosure includes point defects, line defects, and surface defects. For example, basal plane dislocations, micropipes, stacking faults, and lattice defects may be defects. For example, lattice defects function as recombination centers and may be formed due to ion implantation as described later.

Silicon carbide as a semiconductor material has a wider band gap and a higher dielectric breakdown field strength than silicon. This contributes to an increase in impurity concentration and a reduction in resistance, and thus contributes to a reduction in loss in switching of a semiconductor device. Silicon carbide also has high thermal conductivity and thus has excellent heat dissipation, and contributes to high efficiency and low loss of a semiconductor device made of silicon carbide.

In the following preferred embodiments and modifications, description will be made by taking, as an example, silicon carbide in which expansion of stacking faults tends to be remarkable as a semiconductor material. However, the following preferred embodiments and modifications can be achieved by using a semiconductor material other than silicon carbide.

### 1. First Preferred Embodiment

### <1-1. Configuration of Planar Insulated Gate Field Effect Transistor>

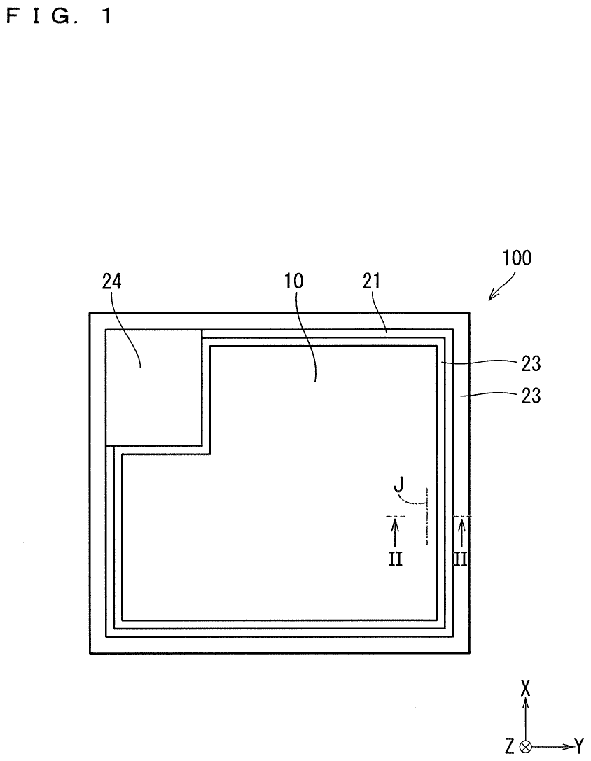

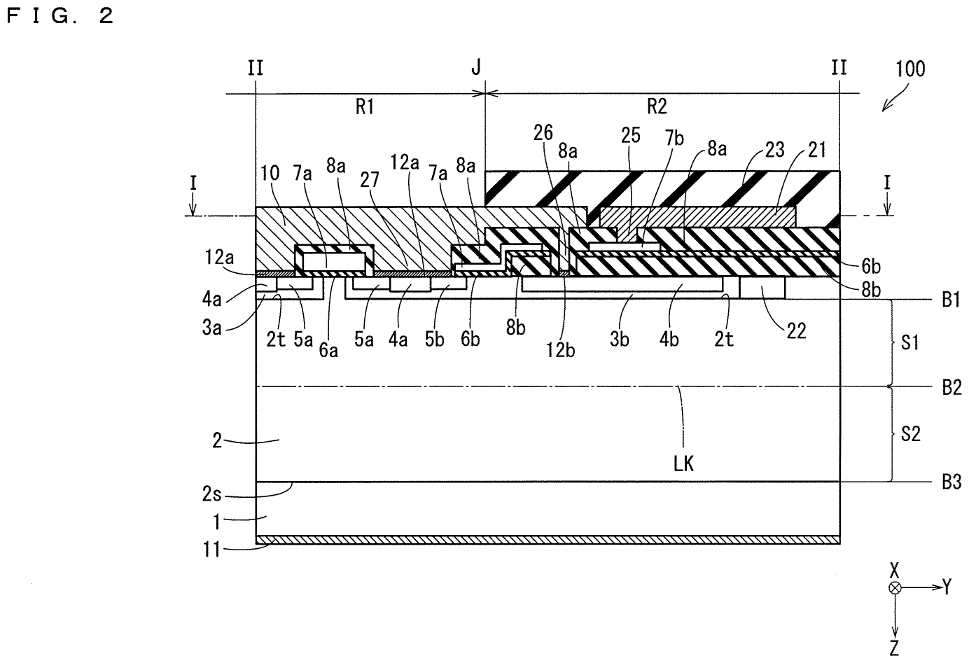

FIGS. 1 and 2 are both cross-sectional views schematically illustrating a semiconductor device 100 according to a first preferred embodiment of the present disclosure. FIG. 2 is a cross-sectional view of the semiconductor device 100 when a position II-II in FIG. 1 is viewed in a direction X. FIG. 1 is a cross-sectional view of the semiconductor device 100 when a position I-I in FIG. 2 is viewed in a direction Z. Hereinafter, the situation viewed in the direction Z is also referred to as “in plan view” for convenience.

The semiconductor device 100 includes an active region R1 and a termination region R2. A position J is a boundary between the active region R1 and the termination region R2. The active region R1 functions as an insulated gate field effect transistor in the semiconductor device 100. The termination region R2, for example, mitigates electric field concentration at an end portion of the active region R1, and suppresses deterioration of the breakdown voltage of the insulated gate field effect transistor. The termination region R2 is adjacent to the active region R1, and surrounds the active region R1 in plan view, for example.

The semiconductor device 100 includes an electrode 10, a gate pad 24, a gate wiring 21, and a protective insulating film 23, which appear in FIG. 1. The gate pad 24 and the gate wiring 21 are electrically connected, and for example, both are continuous. A gate voltage for controlling whether conduction of the semiconductor device 100 is possible is applied to the gate pad 24.

As illustrated in FIG. 2, the semiconductor device 100 includes a substrate 1 and semiconductor layers 2, 3a, 3b. The substrate 1 is made of an n-type low-resistance silicon carbide. The semiconductor layer 2 is made of an n-type silicon carbide having a resistivity higher than that of the substrate 1, and has surfaces 2s, 2t. The surface 2s is adjacent to the substrate 1. The surface 2t faces the surface 2s in the direction Z. For example, the surface 2s is flat, and the surface 2t has irregularities. For example, the semiconductor layer 2 is a so-called epitaxial layer formed by epitaxial growth on the substrate 1. After the epitaxial growth, the semiconductor layers 3a, 3b are formed on the semiconductor layer 2, and thus, the surface 2t has irregularities.

The semiconductor device 100 includes an electrode 11. The electrode 11 is adjacent to the substrate 1 from the side opposite to the semiconductor layer 2.

### <1-1-1. Active Region R1>

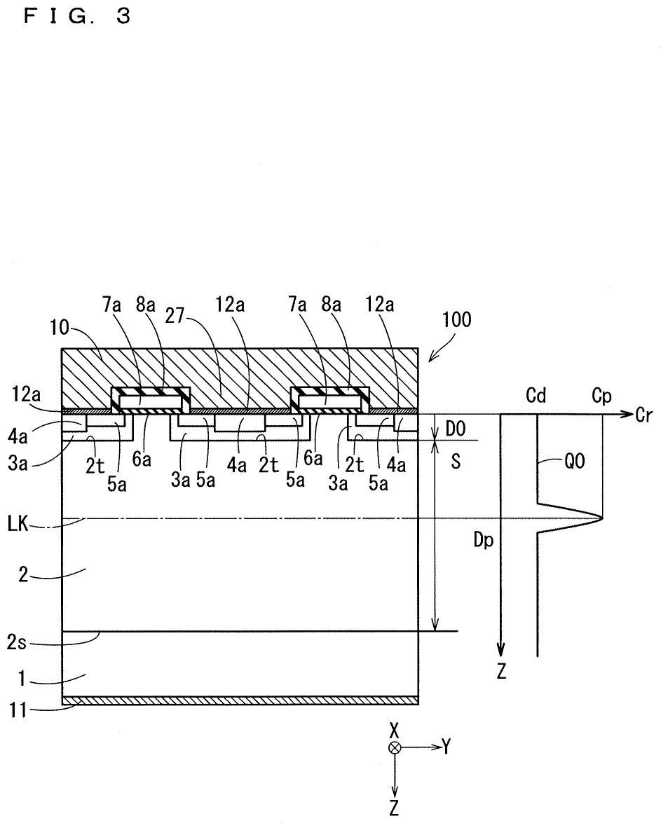

FIG. 3 is a cross-sectional view schematically illustrating the semiconductor device 100 in a part of the active region R1. The cross section is viewed in the direction X. The cross section may appear as viewed in a direction Y. In FIG. 3, a distribution Q0 in the direction Z of a concentration Cr of recombination centers is also schematically illustrated.

The semiconductor layer 3a is located in the active region R1 and is adjacent to the surface 2t. The semiconductor layer 3a is made of a p-type silicon carbide. FIGS. 2 and 3 illustrate a case where the semiconductor layer 3a is located at a concave portion of the surface 2t and exhibits a so-called well region.

A plurality of semiconductor layers 3a may be arranged separately as illustrated, or may be connected to each other.

The semiconductor device 100 includes a semiconductor layer 5a. The semiconductor layer 5a is adjacent to the semiconductor layer 3a from the side opposite to the semiconductor layer 2. The semiconductor layer 5a is separated from the surface 2t. The semiconductor layer 5a is made of an n-type silicon carbide.

A semiconductor layer 4a is located in the active region R1 and is adjacent to the semiconductor layer 3a from the side opposite to the semiconductor layer 2. The semiconductor layer 4a is separated from the surface 2t. The semiconductor layer 4a is also adjacent to the semiconductor layer 5a. The semiconductor layer 4a is made of a p-type silicon carbide. The resistivity of the semiconductor layer 4a is lower than the resistivity of the semiconductor layer 3a. The semiconductor layer 4a is also commonly referred to as well junction region.

An electrode 12a is adjacent to the semiconductor layers 4a, 5a from the side opposite to the semiconductor layer 2. The electrode 10 is adjacent to the electrode 12a from the side opposite to the semiconductor layer 2. The electrode 12a and the electrode 10 are electrically connected. For the electrode 12a, a material that achieves an ohmic junction between the semiconductor layers 4a, 5a and the electrode 10 is adopted. The semiconductor layer 4a and the electrode 12a contribute to easy exchange of electrons and holes between the semiconductor layer 3a and the electrode 10. The electrode 12a contributes to easy exchange of electrons and holes between the semiconductor layer 5a and the electrode 10.

The semiconductor device 100 includes an insulating layer 6a and a conductive layer 7a. For example, the insulating layer 6a is made of silicon oxide. For example, the conductive layer 7a is made of polycrystalline silicon (also commonly referred to as “polysilicon”).

The insulating layer 6a reaches the semiconductor layer 5a from the semiconductor layer 2 across the semiconductor layer 3a while being adjacent to the semiconductor layers 2, 3a, 5a. The conductive layer 7a faces the semiconductor layer 3a with the insulating layer 6a interposed therebetween. The conductive layer 7a is connected to the gate wiring 21 via a conductive layer 7b to be described later, for example, in the termination region R2. The conductive layer 7a is electrically connected to the gate pad 24 and functions as a gate electrode. In the semiconductor device 100, both the insulating layer 6a and the conductive layer 7a extend in the direction Y to form a so-called planar insulated gate.

In the semiconductor layer 3a facing the conductive layer 7a, the vicinity of the conductive layer 7a is commonly referred to as channel region. The substrate 1, the electrode 11, the semiconductor layer 2, the semiconductor layer 5a, and the electrode 10 function as a drain region, a drain electrode, a drift region, a source region, and a source electrode of the insulated gate field effect transistor, respectively.

The conductive layer 7a is covered with an interlayer insulating film 8a from the side opposite to the semiconductor layer 2. The interlayer insulating film 8a is interposed between the conductive layer 7a and the electrode 10 to insulate them from each other. The interlayer insulating film 8a is made of, for example, silicon oxide.

The semiconductor device 100 includes the semiconductor layer 3b. The semiconductor layer 3b is continuously located not only in the active region R1 but also in the termination region R2.

The semiconductor layer 3b is adjacent to the surface 2t. The semiconductor layer 3b is made of a p-type silicon carbide. FIG. 2 illustrates a case where the semiconductor layer 3b is located at the concave portion of the surface 2t and exhibits a so-called well region. The semiconductor layers 3a, 3b are separated by the semiconductor layer 2, for example, by a convex portion of the surface 2t.

The semiconductor device 100 includes a semiconductor layer 5b. The semiconductor layer 5b is adjacent to the semiconductor layer 3b from the side opposite to the semiconductor layer 2 in the active region R1. The semiconductor layer 5b is separated from the surface 2t. The semiconductor layer 5b is made of an n-type silicon carbide. The semiconductor layer 5b is adjacent to the semiconductor layer 4a which is proximate to the termination region R2. Here, “proximate” refers to a situation in which another semiconductor layer 4a is not located between the semiconductor layer 4a and the termination region R2. For example, the semiconductor layers 5a, 4a, 5b are arranged in this order in the direction Y.

The electrode 12a is adjacent to the semiconductor layer 4a and the semiconductor layers 5a, 5b adjacent to the semiconductor layer 4a from the side opposite to the semiconductor layer 2. The electrode 12a also achieves an ohmic junction between the semiconductor layer 5b and the electrode 10.

A hole 27 is opened in the interlayer insulating film 8a. The electrode 12a is exposed from the interlayer insulating film 8a in the hole 27. The electrode 10 is connected to the electrode 12a in the hole 27. The hole 27 is also commonly referred to as contact hole. Since the hole 27 is opened in the active region R1, the hole 27 may be referred to as active region contact hole.

### <1-1-2. Termination Region R2>

The semiconductor device 100 includes a semiconductor layer 4b and a field insulating film 8b in the termination region R2. The semiconductor layer 4b is adjacent to the semiconductor layer 3b from the side opposite to the semiconductor layer 2. For example, the semiconductor layers 4a, 5b, 4b are arranged in this order in the direction Y. The semiconductor layer 4b is separated from the surface 2t. The semiconductor layer 4b is made of a p-type silicon carbide. The resistivity of the semiconductor layer 4b is lower than the resistivity of the semiconductor layer 3b. The semiconductor layer 4b is also commonly referred to as well contact region.

The field insulating film 8b covers the semiconductor layers 2, 3b, 4b in the termination region R2 and a termination structure 22 to be described later from the side opposite to the semiconductor layer 2 except for the position J and the vicinity thereof and a region in which a hole 26 to be described later is opened.

An insulating layer 6b covers the end of the semiconductor layer 5b on the termination region R2 side, the semiconductor layer 3b not covered with the field insulating film 8b, and the field insulating film 8b from the side opposite to the semiconductor layer 2 except for a region where the hole 26 to be described later is opened. The thickness of the insulating layer 6b is designed to be equal to the thickness of the insulating layer 6a, for example. The field insulating film 8b is designed to be thicker than the insulating layer 6b, for example.

The conductive layer 7a covers the insulating layer 6b from the side opposite to the semiconductor layer 2 from the end of the semiconductor layer 5b on the termination region R2 side to the end of the semiconductor layer 4b on the active region R1 side. The conductive layer 7b faces the semiconductor layer 4b with the field insulating film 8b and the insulating layer 6b interposed therebetween. The conductive layers 7a, 7b are arranged in the direction Y.

The interlayer insulating film 8a covers the field insulating film 8b, the insulating layer 6b, and the conductive layers 7a, 7b from the side opposite to the semiconductor layer 2 except for a region where holes 25, 26 to be described later are opened from the end of the semiconductor layer 5b on the termination region R2 side to the termination region R2.

The hole 26 is opened in the insulating layer 6b and the field insulating film 8b. The hole 26 penetrates the insulating layer 6b. In the hole 26, the electrode 12b is adjacent to the semiconductor layer 4b from the side opposite to the semiconductor layer 2. The electrode 12b is exposed from the interlayer insulating film 8a, the field insulating film 8b, and the insulating layer 6b in the hole 26.

The electrode 10 is adjacent to the electrode 12b from the side opposite to the semiconductor layer 2. The electrode 10 is connected to the electrode 12b in the hole 26. For the electrode 12b, a material that achieves an ohmic junction between the electrode 10 and the semiconductor layer 4b is adopted. The electrode 10 is connected to the electrode 12b in the hole 26. The semiconductor layer 4b and the electrode 12b contribute to easy exchange of electrons and holes between the semiconductor layer 3b and the electrode 10.

The hole 26 is also commonly referred to as contact hole. Since the hole 26 is opened in the termination region R2, the hole 26 can be referred to as termination region contact hole.

The electrode 12b does not achieve an ohmic junction between the semiconductor layer 3b and the electrode 10, and does not connect the semiconductor layers 3b, 4b. For example, in plan view, the hole 26 is located in a region occupied by the semiconductor layer 4b, and the electrode 12b is not adjacent to the semiconductor layer 3b.

The range in which the semiconductor layer 4b is formed in the direction Y in the cross section viewed in the direction X is not necessarily over the entire semiconductor layer 3b, and may be partial.

A hole 25 is opened in the interlayer insulating film 8a in the termination region R2. A part of the conductive layer 7b is exposed from the interlayer insulating film 8a in the hole 25.

The gate wiring 21 partially covers the interlayer insulating film 8a in the termination region R2, and is connected to the conductive layer 7b in the hole 25. The conductive layer 7a is electrically connected to the gate pad 24 via the gate wiring 21 and the conductive layer 7b, and functions as a gate electrode.

The hole 25 is also commonly referred to as contact hole. Since the hole 25 is involved in the connection between the gate wiring 21 and the conductive layer 7b, the hole 25 may be referred to as gate contact hole.

The semiconductor device 100 includes the termination structure 22 in the termination region R2. The termination structure 22 is located on the side opposite to the semiconductor layer 3a with respect to the semiconductor layer 3b. For example, the termination structure 22 is adjacent to the semiconductor layer 3b. For example, a structure, which is commonly referred to as junction termination extension (JTE) and uses a p-type silicon carbide having an impurity concentration lower than that of the semiconductor layer 3b, is adopted as the termination structure 22. Alternatively, for example, a structure commonly referred to as field limiting ring (FLR) is adopted as the termination structure 22. Alternatively, for example, a structure in which JTE and FLR are combined may be adopted as the termination structure 22.

The semiconductor device 100 includes the protective insulating film 23. The protective insulating film 23 covers the electrode 10, the interlayer insulating film 8a, and at least a part of the gate wiring 21 from the side opposite to the semiconductor layer 2 in the termination region R2. FIG. 2 illustrates a state in which the entire gate wiring 21 is covered with the protective insulating film 23.

### <1-2. Concentration Distribution of Recombination Centers>

When a defect exists in the substrate 1 or the semiconductor layer 2 and a current is applied between the electrode 10 and the electrode 11, carriers injected into the semiconductor layer 2 are captured by the defect. Such capture reduces defect energy and causes expansion of stacking faults. This tendency is remarkable when silicon carbide is adopted as a semiconductor material.

Disappearance of the carriers at the recombination centers before the carriers are captured by the defect suppresses the capture and thus contributes to suppression of expansion of the stacking faults inherent in the semiconductor layer 2.

The semiconductor layer 2 has recombination centers. For example, recombination centers are introduced into the semiconductor layer 2 by implantation of protons or helium. Such recombination centers function as the lifetime killer described in Japanese Patent Application Laid-Open No. 2022-17550.

In FIGS. 2 and 3, a position LK where the concentration Cr exhibits a local maximum Cp, which is the concentration peak in the distribution Q0, is indicated.

Referring to FIG. 3, the concentration Cr has the distribution Q0 between a value Cd and the local maximum Cp. The value Cd indicates the concentration Cr in a region where the variation is minute for convenience, and may actually have a minute variation range. For example, the value Cd serves as a baseline for the concentration Cr.

The position LK is between the surfaces 2s, 2t and is separated from the surface 2s. The position LK is between the semiconductor layer 3a and the surface 2s. Referring to FIG. 2, the semiconductor layer 2 is divided into a region S1 extending from a position B1 to a position B2 and a region S2 extending from the position B2 to a position B3 in the direction Z. FIG. 2 illustrates a case where the bottom of the concave portion of the surface 2t, the position LK, and the surface 2s are independent of the direction Y.

The position B1 is a position in the direction Z of the bottom of the concave portion of the surface 2t. The position B1 can also be regarded as a position in the direction Z of the end of the semiconductor layer 3a on the surface 2s side. The position B2 is a position in the direction Z of the position LK. The position B3 is a position in the direction Z of the surface 2s.

According to Japanese Patent Application Laid-Open No. 2022-17550, protons are implanted in the vicinity of the interface between the epitaxial layer and the substrate. Thus, by the application of the current, the stacking faults in the epitaxial layer may extend from the substrate side of the epitaxial layer to the opposite side of the epitaxial layer.

On the other hand, in the semiconductor device 100, a local maximum appears in the concentration of recombination centers at the position B2 away from the surface 2s in the semiconductor layer 2 as the epitaxial layer. Therefore, even if the stacking faults expand in the epitaxial layer due to the application of the current, the range of the expansion is limited to only one of the regions S1 and S2. This contributes to reducing the area of the stacking faults, which expand, as compared with conventional cases.

The position LK can be estimated by measuring an ion concentration distribution in the semiconductor layer 2 when protons or helium is implanted, for example, using secondary ion mass spectrometry (SIMS). After the semiconductor device 100 is manufactured, deep level transient spectroscopy (DLTS) measurement in the semiconductor layer 2 can be performed to estimate the position LK.

As described below, the end of the semiconductor layer 3a on the side opposite to the semiconductor layer 2, the ends of the semiconductor layers 4a, 5a on the side opposite to the semiconductor layer 2, and a position of the surface 2t farthest from the surface 2s (also referred to as end of the convex portion of the surface 2t) are at the same position in the direction Z, and the position is set as a reference position in the direction Z.

A following inequality (1) is expressed by introducing a thickness DO of the semiconductor layer 3a in the direction Z (also referred to as distance from the reference position of the position B1 in the above assumption), a thickness S of the semiconductor layer 2 from the surface 2s to the semiconductor layer 3a in the direction Z, and a distance Dp from the reference position (also referred to as distance from the reference position of the position B2). The local maximum Cp appears in the distribution Q0 at the distance Dp satisfying the inequality. In this case, the position LK is at the distance Dp from the reference position.

$$D 0 < D p < D 0 + S \qquad ( 1 )$$

When the concentration Cr is not taken into consideration, the stacking faults may expand to the semiconductor layer 2 between the surface 2s and the semiconductor layer 3a. Even if the stacking faults expand in the semiconductor layer 2 by the application of the current, when the concentration Cr has a concentration peak at the position LK, the range of the expansion is limited to only one of the regions S1 and S2.

Therefore, when the distance Dp satisfies a following formula (2) (at this time, the inequality (1) is always satisfied), the range in which the stacking faults expand does not exceed half of the range in the case where recombination centers are not introduced. When the distance Dp satisfies the following formula (2), the effect of suppressing the expansion of the stacking faults is higher compared to cases when the distance Dp does not satisfy the following formula (2) even if the inequality (1) is satisfied.

$$D p = D 0 + ( 1 / 2 ) S \qquad ( 2 )$$

It can be said that when the formula (2) is satisfied, the local maximum Cp appears in the distribution Q0 at the center in the direction Z between the semiconductor layer 3a and the surface 2s.

### 2. Second Preferred Embodiment

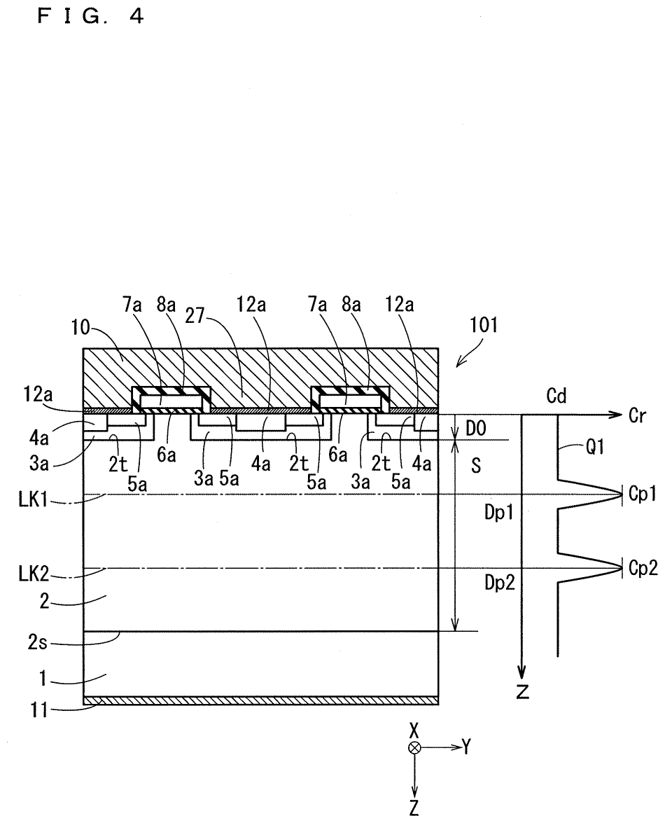

FIG. 4 is a cross-sectional view schematically illustrating a semiconductor device 101 according to a second preferred embodiment of the present disclosure. Similarly to FIG. 3, FIG. 4 illustrates a cross section of the semiconductor device 101 in a part of the active region R1 (see FIG. 2) as viewed in the direction X. The cross section may appear as viewed in the direction Y. FIG. 4 also schematically illustrates a distribution Q1 in the direction Z of the concentration Cr of recombination centers.

The difference between the semiconductor device 101 and the semiconductor device 100 is the difference between the distribution Q1 and the distribution Q0. Therefore, other description of the semiconductor layer, the conductive layer, and the insulating film, for example, is omitted.

The concentration Cr has a plurality of local maxima Cp1 and Cp2. At the distances Dp1 and Dp2 in the direction Z, the local maxima Cp1 and Cp2 appear in the distribution Q1, respectively.

In FIG. 4, positions LK1 and LK2 indicate positions where the local maxima Cp1 and Cp2 appear, respectively. The position LK1 is at the distance Dp1 from the reference position in the direction Z. The position LK2 is at the distance Dp2 from the reference position in the direction Z. An inequality (3) is expressed by introducing the thicknesses D0 and S as in the first preferred embodiment. The local maxima Cp1 and Cp2 appear in the distribution Q1 at the distances Dp1 and Dp2 satisfying the inequality, respectively.

$$D 0 < Dp 1 < Dp 2 < D 0 + S \qquad ( 3 )$$

When the distances Dp1 and Dp2 satisfy a following formula (4) (at this time, the inequality (3) is always satisfied), the range in which the stacking faults expand does not exceed ⅓ of the range in the case where recombination centers are not introduced. When the distances Dp1 and Dp2 satisfy the following formula (4), the effect of suppressing the expansion of the stacking faults is higher compared to cases when the distances Dp1 and Dp2 do not satisfy the following formula (4) even if the inequality (3) is satisfied.

$$Dp 1 = D 0 + ( 1 \text{/3} ) S , Dp 2 = D 0 + ( 2 / 3 ) S \qquad ( 4 )$$

In the semiconductor layer 2, the concentration Cr may take a local maximum at three or more positions in the direction Z. For example, when the number of the positions is n and the positions are at the distances Dp1, Dp2, . . . , and Dpn from the reference position in the direction Z, respectively, a following formula (5) is satisfied by introducing an integer r of 1 or more and n or less. At this time, positions where the concentration Cr takes a local maximum are at equal intervals in the direction Z. When the following formula (5) is satisfied, the effect of suppressing the expansion of the stacking faults is enhanced. This is because the range in which the stacking faults expand does not exceed 1/(n+1) of the range at the time when recombination centers are not introduced.

$$Dpr = D 0 + ( r / ( n + 1 ) ) S \qquad ( 5 )$$

### 3. Third Preferred Embodiment

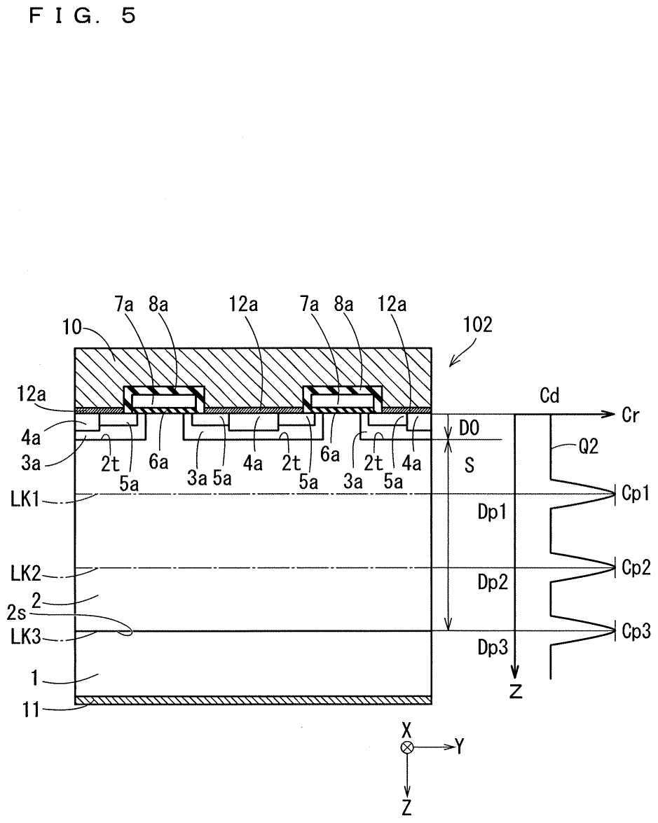

FIG. 5 is a cross-sectional view schematically illustrating a semiconductor device 102 according to a third preferred embodiment of the present disclosure. Similarly to FIG. 3, FIG. 5 illustrates a cross section of the semiconductor device 102 in a part of the active region R1 (see FIG. 2) as viewed in the direction X. The cross section may appear as viewed in the direction Y. FIG. 5 also schematically illustrates a distribution Q2 in the direction Z of the concentration Cr of recombination centers.

The difference between the semiconductor device 102 and the semiconductor device 100 is the difference between the distribution Q2 and the distribution Q0. Therefore, other description of the semiconductor layer, the conductive layer, and the insulating film, for example, is omitted.

The concentration Cr has a plurality of local maxima Cp1, Cp2, and Cp3. At a plurality of distances Dp1, Dp2, and Dp3 in the direction Z, the local maxima Cp1, Cp2 and Cp3 appear in the distribution Q2, respectively.

In FIG. 5, positions LK1, LK2, and LK3 indicate positions at which the local maxima Cp1, Cp2, and Cp3 appear, respectively. The position LK1 is at the distance Dp1 from the reference position in the direction Z. The position LK2 is at the distance Dp2 from the reference position in the direction Z.

As in the second preferred embodiment, the thicknesses D0 and S are introduced, and the local maxima Cp1 and Cp2 appear in the distribution Q2 at the distances Dp1 and Dp2 satisfying the inequality (3), respectively. When the formula (4) is satisfied as in the second preferred embodiment, the effect of suppressing the expansion of the stacking faults is higher compared to cases when the following formula (4) is not satisfied even if the inequality (3) is satisfied.

Unlike the semiconductor device 101, the semiconductor device 102 has the local maximum Cp3 in the distribution Q2 at a distance (D0+S) from the reference position in the direction Z. It can be said that the local maximum Cp3 also appears in the distribution Q2 on the surface 2s. It can also be said that the position LK3 is at the interface between the substrate 1 and the semiconductor layer 2.

The fact that the concentration of recombination centers has a local maximum at the position LK3 contributes to suppressing the expansion of the stacking faults starting from a basal plane dislocation which is present in the substrate 1.

There may be no position LK1 in the semiconductor device 102. In this case, the position LK2 is treated as equivalent to the position LK indicated in the semiconductor device 100. Alternatively, there may be no position LK2 in the semiconductor device 102. In this case, the position LK1 is treated as equivalent to the position LK indicated in the semiconductor device 100. As in the first preferred embodiment, the inequality (1) is satisfied, and preferably, the formula (2) is also satisfied.

As in the second preferred embodiment, when there are n positions where the concentration Cr takes a local maximum and the positions are at the distances Dp1, Dp2, . . . , and Dpn from the reference position in the direction Z, respectively, a following formula (6) is satisfied by introducing an integer r of 1 or more and n or less. At this time, positions where the concentration Cr takes a local maximum are at equal intervals in the direction Z. It can also be said that the surface 2s is at the distance Dpn from the reference position.

When the following formula (6) is satisfied, the effect of suppressing the expansion of the stacking faults is enhanced. This is because the range in which the stacking faults expand does not exceed 1/n of the range at the time when recombination centers are not introduced.

$$Dpr = D 0 + ( r / n ) S \qquad ( 6 )$$

### 4. Fourth Preferred Embodiment

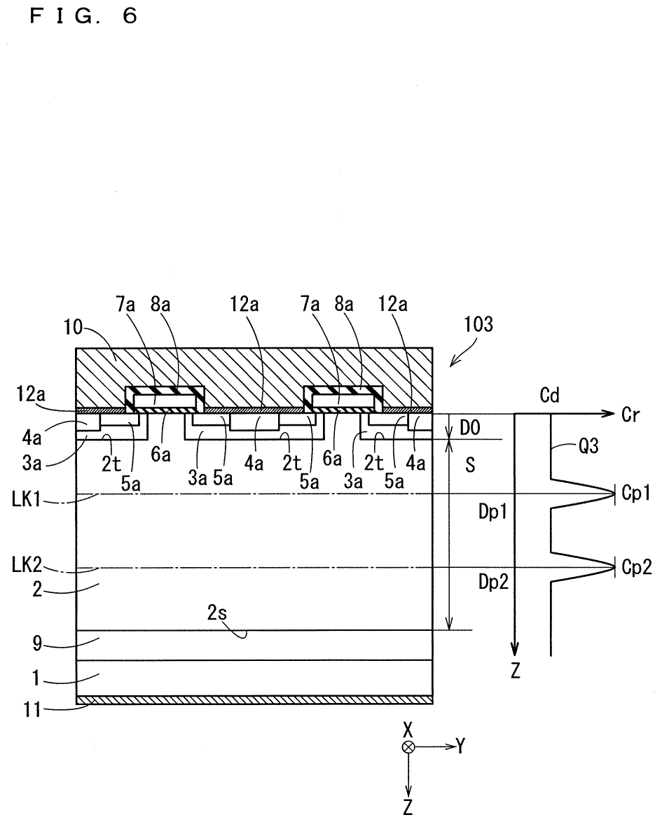

FIG. 6 is a cross-sectional view schematically illustrating a semiconductor device 103 according to a fourth preferred embodiment of the present disclosure. Similarly to FIG. 3, FIG. 6 illustrates a cross section of the semiconductor device 103 in a part of the active region R1 (see FIG. 2) as viewed in the direction X. The cross section may appear as viewed in the direction Y. FIG. 6 also schematically illustrates a distribution Q3 in the direction Z of the concentration Cr of recombination centers.

The difference between the semiconductor device 103 and the semiconductor device 101 is the presence or absence of a semiconductor layer 9, and the distribution Q3 is not substantially different from the distribution Q1. Therefore, other description of the semiconductor layer, the conductive layer, and the insulating film, for example, is omitted.

The semiconductor device 103 includes the semiconductor layer 9. The semiconductor layer 9 is located between the substrate 1 and the semiconductor layer 2. The semiconductor layer 2, the semiconductor layer 9, and the substrate 1 are arranged in this order in the direction Z. The semiconductor layer 9 functions as the boundary layer described in Japanese Patent Application Laid-Open No. 2022-17550, for example. Alternatively, the semiconductor layer 9 may be commonly referred to as buffer layer, for example.

The semiconductor layer 9 is made of an n-type silicon carbide. The impurity concentration of the semiconductor layer 9 is higher than the impurity concentration of the semiconductor layer 2. For example, the impurity concentration of the semiconductor layer 9 is 1×10¹⁸ cm⁻³ or more and 1×10¹⁹ cm⁻³ or less, and the maximum value of the impurity concentration of the semiconductor layer 2 is less than 1×10¹⁸ cm⁻³. For example, the impurity concentration of the semiconductor layer 9 may be 5×10¹⁸ cm⁻³ or less. The thickness of the semiconductor layer 9 is, for example, 0.5 μm or more and 5 μm or less.

For example, the semiconductor layer 9 is an epitaxial layer obtained by epitaxial growth on the substrate 1. For example, the semiconductor layers 2, 9 are both epitaxial layers with respect to the substrate 1, and are distinguished from each other by the above-described impurity concentration.

The fact that the semiconductor layer 9 has the above-described impurity concentration and the above-described thickness contributes to suppressing the expansion of the stacking faults starting from the basal plane dislocation which is present in the substrate 1 even when a current is applied at a high current density of 500 A/cm² or more, for example. The thickness of the semiconductor layer 9 may be reduced to 0.3 μm or may be increased to 10 μm.

The semiconductor device 103 has the effect of the semiconductor layer 9 described above in addition to the effect of the semiconductor device 101.

In the semiconductor device 103, similarly to the semiconductor device 102, either one of the positions LK1 and LK2 may be omitted. When there is no position LK1, the position LK2 is treated as equivalent to the position LK indicated in the semiconductor device 100. When there is no position LK2, the position LK1 is treated as equivalent to the position LK indicated in the semiconductor device 100. As in the first preferred embodiment, the inequality (1) is satisfied, and preferably, the formula (2) is also satisfied.

As in the second preferred embodiment, for example, when there are n positions where the concentration Cr takes a local maximum and the positions are at the distances Dp1, Dp2, . . . , and Dpn from the reference position in the direction Z, respectively, the formula (5) is satisfied by introducing an integer r of 1 or more and n or less.

### 5. Fifth Preferred Embodiment

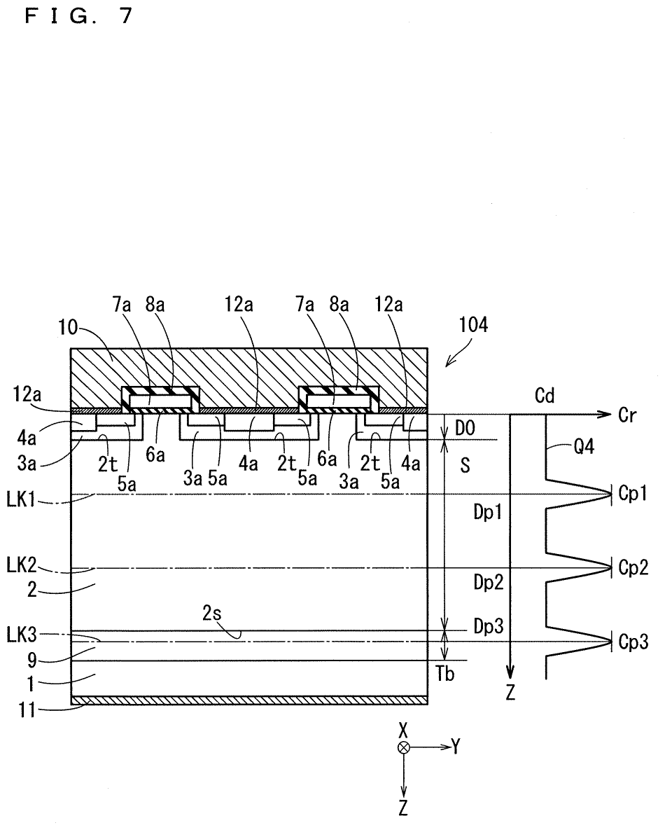

FIG. 7 is a cross-sectional view schematically illustrating a semiconductor device 104 according to a fifth preferred embodiment of the present disclosure. Similarly to FIG. 3, FIG. 7 illustrates a cross section of the semiconductor device 104 in a part of the active region R1 (see FIG. 2) as viewed in the direction X. The cross section may appear as viewed in the direction Y. FIG. 7 also schematically illustrates a distribution Q4 in the direction Z of the concentration Cr of recombination centers.

The difference between the semiconductor device 104 and the semiconductor device 103 lies in the presence or absence of the position LK3 where the concentration takes a local maximum. Therefore, other description of the semiconductor layer, the conductive layer, and the insulating film, for example, is omitted.

Similarly to the semiconductor device 103, the semiconductor device 104 further includes the semiconductor layer 9. The position LK3 is in the semiconductor layer 9. The position LK3 may be on the surface 2s or may be at the interface between the semiconductor layer 9 and the substrate 1.

An inequality (7) is expressed by introducing a thickness Tb of the semiconductor layer 9 in the direction Z and the plurality of distances Dp1, Dp2, and Dp3 (see the third preferred embodiment and the inequality (3)) in the direction Z exhibiting the local maxima Cp1, Cp2, and Cp3, respectively, in the distribution Q4.

$$D 0 < Dp 1 < Dp 2 < D 0 + S ≦ Dp 3 ≦ D 0 + S + Tb \qquad ( 7 )$$

Due to the presence of the position LK3, the semiconductor device 104 obtains the effect of the semiconductor layer 9 even if the thickness Tb and the impurity concentration of the semiconductor layer 9 are reduced as compared with the semiconductor device 103. The semiconductor device 104 can obtain the same effect at a lower cost as compared with the semiconductor device 103.

Due to the presence of the semiconductor layer 9, the semiconductor device 104 extends the range of the current density capable of suppressing the expansion of the stacking faults starting from the basal plane dislocation which is present in the substrate 1 to a higher level compared to the semiconductor device 102.

When the distances Dp1 and Dp2 satisfy the formula (4), the range in which the stacking faults expand does not exceed ⅓ of the range in the case where recombination centers are not introduced. When the distances Dp1 and Dp2 satisfy the formula (4), the effect of suppressing the expansion of the stacking faults is higher compared to cases when the distances Dp1 and Dp2 do not satisfy the formula (7) even if the inequality (7) is satisfied.

The surface 2s is directly adjacent to the substrate 1 in the semiconductor devices 100, 101, 102, and is indirectly adjacent to the substrate 1 with the semiconductor layer 9 interposed therebetween in the semiconductor devices 103, 104. Therefore, the semiconductor layer 2 can also be expressed as being directly or indirectly adjacent to the substrate 1.

Alternatively, the substrate 1 includes a region adjacent to the surface 2s on the semiconductor layer 2 side with the above-described impurity concentration, and the region can be regarded as the semiconductor layer 9. At this time, it can also be said that the semiconductor layer 2 is adjacent to the substrate 1, particularly adjacent to the semiconductor layer 9 as the region.

In the semiconductor device 104, similarly to the semiconductor device 102, either one of the positions LK1 and LK2 may be omitted. When there is no position LK1, the position LK2 is treated as equivalent to the position LK indicated in the semiconductor device 100. When there is no position LK2, the position LK1 is treated as equivalent to the position LK indicated in the semiconductor device 100. As in the first preferred embodiment, the inequality (1) is satisfied, and preferably, the formula (2) is also satisfied.

As in the third preferred embodiment, when there are n positions where the concentration Cr takes a local maximum and the positions are at the distances Dp1, Dp2, . . . , and Dpn from the reference position in the direction Z, respectively, a following formula (8) is satisfied by introducing an integer q which is 1 or more and less than n. When the following formula (8) is satisfied, the effect of suppressing the expansion of the stacking faults is enhanced. This is because the range in which the stacking faults expand does not exceed 1/n of the range at the time when recombination centers are not introduced.

$$Dpq = D 0 + ( q / n ) S , D 0 + S ≦ Dpn ≦ D 0 + S + Tb \qquad ( 8 )$$

### 6. Sixth Preferred Embodiment

### <6-1. Configuration of Trench-Type Insulated Gate Field Effect Transistor>

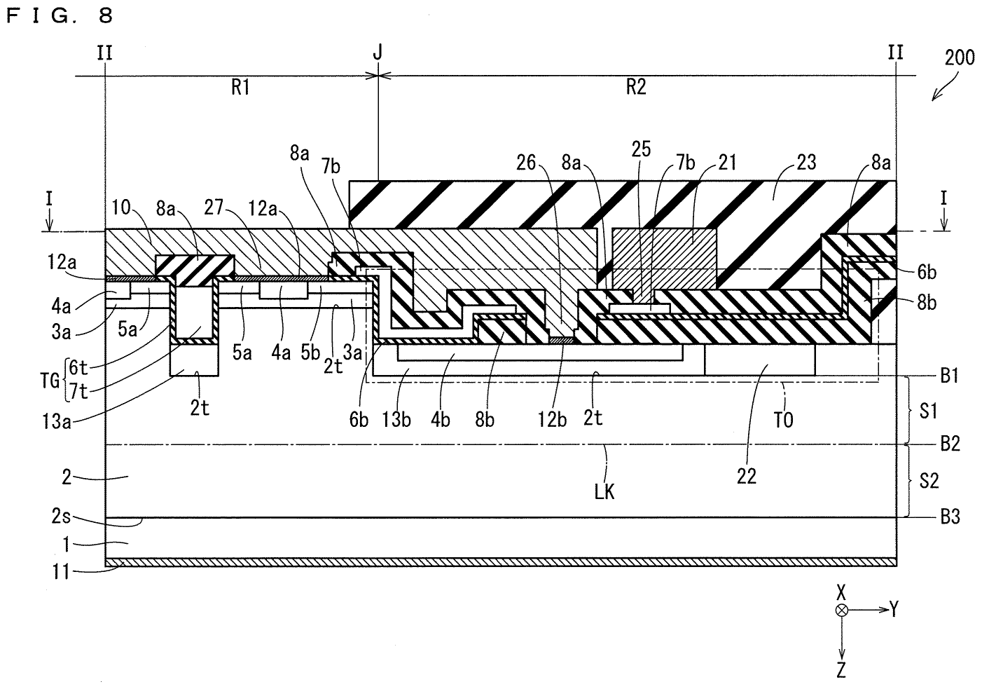

FIG. 8 is a cross-sectional view schematically illustrating a semiconductor device 200 according to a sixth preferred embodiment of the present disclosure. FIG. 8 is a cross-sectional view of the semiconductor device 200 when the position II-II in FIG. 1 is viewed in the direction X. FIG. 1 is also a cross-sectional view of the semiconductor device 200 when the position I-I in FIG. 8 is viewed in the direction Z.

Similarly to the semiconductor devices 100 to 104, the semiconductor device 200 also includes the active region R1 and the termination region R2. The position J is the boundary between the active region R1 and the termination region R2.

As illustrated in FIG. 8, the semiconductor device 200 includes the substrate 1, the semiconductor layers 2, 3a, and the electrode 11. The materials, conductivity types, and resistivity of the substrate 1, the semiconductor layer 2, and the semiconductor layer 3a are the same as those of the first preferred embodiment, and details thereof are omitted.

### <6-1-1. Active Region R1>

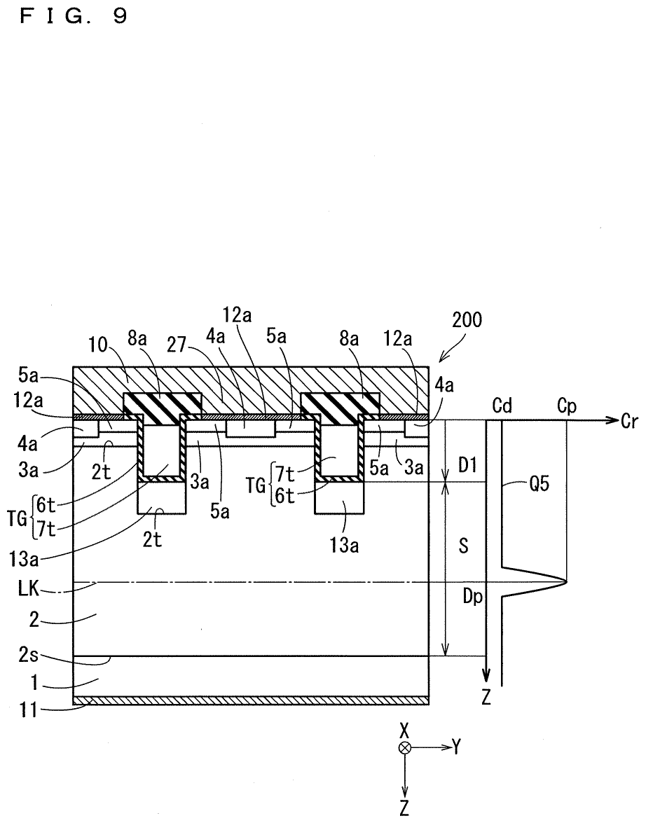

FIG. 9 is a cross-sectional view schematically illustrating the semiconductor device 200 in a part of the active region R1. The cross section is viewed in the direction X. The cross section may appear as viewed in the direction Y. FIG. 9 also schematically illustrates a distribution Q5 in the direction Z of the concentration Cr of recombination centers.

The semiconductor layer 3a is located in the active region R1 and is adjacent to the surface 2t. FIGS. 8 and 9 illustrate a case where the semiconductor layer 3a is adjacent to the convex portion of the surface 2t from the side opposite to the surface 2s.

The semiconductor device 200 includes the semiconductor layers 4a, 5a and the electrodes 10, 12a.

The semiconductor layer 5a is adjacent to the semiconductor layer 3a from the side opposite to the semiconductor layer 2. The semiconductor layer 5a is separated from the surface 2t. The semiconductor layer 5a is made of an n-type silicon carbide.

The semiconductor layer 4a is located in the active region R1 and is adjacent to the semiconductor layer 3a from the side opposite to the semiconductor layer 2. The semiconductor layer 4a is separated from the surface 2t. For example, the semiconductor layers 5a, 3a, 2 are arranged in this order in the direction Z. For example, the semiconductor layers 4a, 3a, 2 are arranged in this order in the direction Z.

The semiconductor layer 4a is made of a p-type silicon carbide. The resistivity of the semiconductor layer 4a is lower than the resistivity of the semiconductor layer 3a. The semiconductor layer 4a is also commonly referred to as well contact region.

The electrode 12a is adjacent to the semiconductor layers 4a, 5a from the side opposite to the semiconductor layer 2. The electrode 10 is adjacent to the electrode 12a from the side opposite to the semiconductor layer 2. The electrode 12a and the electrode 10 are electrically connected. For the electrode 12a, a material that achieves an ohmic junction between the semiconductor layers 4a, 5a and the electrode 10 is adopted. The semiconductor layer 4a and the electrode 12a contribute to easy exchange of electrons and holes between the semiconductor layer 3a and the electrode 10. The electrode 12a contributes to easy exchange of electrons and holes between the semiconductor layer 5a and the electrode 10.

The semiconductor device 200 includes an insulating layer 6t and a conductive layer 7t. For example, the insulating layer 6t is made of silicon oxide. For example, the conductive layer 7t is made of polycrystalline silicon (polysilicon).

The insulating layer 6t is adjacent to the semiconductor layers 2, 3a, 5a, and reaches the semiconductor layer 5a from the semiconductor layer 2 across the semiconductor layer 3a. The conductive layer 7t faces the semiconductor layers 2, 3a, 5a with the insulating layer 6t interposed therebetween.

The conductive layer 7t is connected to the gate wiring 21 via the conductive layer 7b to be described later, for example, in the termination region R2. The conductive layer 7t is electrically connected to the gate pad 24 and functions as a gate electrode. In the semiconductor device 200, both the insulating layer 6t and the conductive layer 7t extend in the direction Z to form a so-called trench-type insulated gate TG.

In the semiconductor layer 3a facing the conductive layer 7t, the vicinity of the conductive layer 7t is commonly referred to as channel region. Similarly to the semiconductor device 100, the substrate 1, the electrode 11, the semiconductor layer 2, and the semiconductor layer 5a function as a drain region, a drain electrode, a drift region, and a source region of the insulated gate field effect transistor, respectively.

The conductive layer 7t is covered with the interlayer insulating film 8a from the side opposite to the semiconductor layer 2. The interlayer insulating film 8a is interposed between the conductive layer 7t and the electrode 10 to insulate them from each other. The interlayer insulating film 8a is made of, for example, silicon oxide.

The semiconductor device 200 includes a semiconductor layer 13a. The semiconductor layer 13a is adjacent to the insulated gate TG and is located at an end of the insulated gate TG on the surface 2s side. The semiconductor layer 13a is adjacent to the surface 2t. The semiconductor layer 13a is made of a p-type silicon carbide. FIG. 9 illustrates a case where the semiconductor layer 13a is located at the concave portion of the surface 2t and surrounded by the insulated gate TG and the semiconductor layer 2. The semiconductor layer 13a contributes to the mitigation of the electric field applied to the insulated gate TG at a position where the insulating layer 6t is bent between the direction Y and the direction Z when viewed in the direction X.

The semiconductor device 200 includes the semiconductor layer 5b. The semiconductor layer 5b is adjacent to the semiconductor layer 3a from the side opposite to the semiconductor layer 2 in the active region R1. The semiconductor layer 5b is separated from the surface 2t. The semiconductor layer 5b is made of an n-type silicon carbide. The semiconductor layer 5b is adjacent to the semiconductor layer 4a which is proximate to the termination region R2. Here, “proximate” refers to a situation in which another semiconductor layer 4a is not located between the semiconductor layer 4a and the termination region R2. For example, the semiconductor layers 5a, 4a, 5b are arranged in this order in the direction Y.

The electrode 12a is adjacent to the semiconductor layer 4a and the semiconductor layers 5a, 5b adjacent to the semiconductor layer 4a from the side opposite to the semiconductor layer 2. The electrode 12a also achieves an ohmic junction between the semiconductor layer 5b and the electrode 10.

The hole 27, which is commonly referred to as contact hole and can be referred to as active region contact hole, is opened in the interlayer insulating film 8a. The electrode 12a is exposed from the interlayer insulating film 8a in the hole 27. The electrode 10 is connected to the electrode 12a in the hole 27.

### <6-1-2. Termination Region R2>

The semiconductor device 200 includes the insulating layer 6b and the conductive layer 7b. The insulating layer 6b and the conductive layer 7b are provided from the active region R1 to the termination region R2 across the position J. Specifically, the insulating layer 6b is provided from above a part of the semiconductor layer 5b on the side opposite to the semiconductor layer 5a to above a part of the termination region R2 on the active region R1 side. In FIG. 8, “above” an object indicates a position farther than the object as viewed from the semiconductor layer 2.

The insulating layer 6b is bent to the surface 2s side from the active region R1 toward the termination region R2 in the vicinity of the position J. At least in the vicinity of the position J, the distance between the insulating layer 6b and the surface 2s in the termination region R2 is shorter than the distance between the insulating layer 6t and the surface 2s in the active region R1.

The conductive layer 7b is provided on the insulating layer 6b from above a part of the semiconductor layer 5b on the side opposite to the semiconductor layer 5a to above a part of the termination region R2 on the active region R1 side. FIG. 8 illustrates a case where the conductive layer 7b does not partially cover the two ends of the insulating layer 6b in a direction (Y direction in FIG. 8) non-parallel to the direction (X direction in FIG. 8) in which the boundary between the active region R1 and the termination region R2 extends. In this case, it can also be said that the two ends of the insulating layer 6b are exposed from the conductive layer 7b.

The conductive layer 7b faces the semiconductor layers 5b, 3a, 2 with the insulating layer 6b interposed therebetween in the direction Y. Therefore, the conductive layer 7b and the insulating layer 6b in the vicinity of the position J may function as the insulated gate TG, similarly to the conductive layer 7t and the insulating layer 6t in the active region R1. At this time, a portion, which faces the conductive layer 7b, of the semiconductor layer 3a in the active region R1 in the vicinity of the position J is a channel region.

The semiconductor device 200 includes the semiconductor layer 4b and a semiconductor layer 13b in the termination region R2. The semiconductor layers 4b, 13b partially cover the surface 2t of the semiconductor layer 2. The semiconductor layer 13b is adjacent to the surface 2t. The semiconductor layer 13b is made of a p-type silicon carbide. FIG. 2 illustrates a case where the semiconductor layer 13b is located at the concave portion of the surface 2t. The semiconductor layers 13a, 13b are separated by the semiconductor layer 2, for example, by the convex portion of the surface 2t.

The semiconductor layer 4b is adjacent to the semiconductor layer 13b from the side opposite to the semiconductor layer 2. The semiconductor layer 4b is separated from the surface 2t. The semiconductor layer 4b is made of a p-type silicon carbide. The resistivity of the semiconductor layer 4b is lower than the resistivity of the semiconductor layer 13b. The semiconductor layer 4b is also commonly referred to as well contact region.

FIG. 8 illustrates a case where the semiconductor layer 4b does not partially cover the two ends of the semiconductor layer 13b in a direction (Y direction in FIG. 8) non-parallel to the direction (X direction in FIG. 8) in which the boundary between the active region R1 and the termination region R2 extends. In this case, it can also be said that the two ends of the semiconductor layer 13b are exposed from the semiconductor layer 4b.

The semiconductor device 200 includes the field insulating film 8b in the termination region R2. The field insulating film 8b covers the semiconductor layers 2, 13b, 4b in the termination region R2 and the termination structure 22 to be described later from the side opposite to the semiconductor layer 2 except for a region in which the hole 26 to be described later is opened.

The insulating layer 6b covers the end of the semiconductor layer 5b on the termination region R2 side, the semiconductor layers 13b, 4b in a region not covered with the field insulating film 8b, and the field insulating film 8b from the side opposite to the semiconductor layer 2. The thickness of the insulating layer 6b is designed to be equal to the thickness of the insulating layer 6t, for example. The field insulating film 8b is designed to be thicker than the insulating layer 6b, for example.

The conductive layer 7b covers the insulating layer 6b from the side opposite to the semiconductor layer 2 from the end of the semiconductor layer 5b on the termination region R2 side to the end of the semiconductor layer 4b on the active region R1 side across the semiconductor layer 13b. The conductive layer 7b faces the semiconductor layer 4b with the insulating layer 6b interposed therebetween or with the field insulating film 8b and the insulating layer 6b interposed therebetween.

The interlayer insulating film 8a covers the field insulating film 8b, the insulating layer 6b, and the conductive layer 7b from the side opposite to the semiconductor layer 2 except for a region where the holes 25, 26 to be described later are opened from the end of the semiconductor layer 5b on the termination region R2 side to the termination region R2.

The hole 26 is opened in the insulating layer 6b and the field insulating film 8b. The hole 26 penetrates the insulating layer 6b. In the hole 26, the electrode 12b is adjacent to the semiconductor layer 4b from the side opposite to the semiconductor layer 2. The electrode 10 is adjacent to the electrode 12b from the side opposite to the semiconductor layer 2. The electrode 12b and the electrode 10 are electrically connected. The electrode 12b is exposed from the interlayer insulating film 8a, the field insulating film 8b, and the insulating layer 6b in the hole 26.

The electrode 10 is adjacent to the electrode 12b from the side opposite to the semiconductor layer 2. The electrode 10 is connected to the electrode 12b in the hole 26. For the electrode 12b, a material that achieves an ohmic junction between the electrode 10 and the semiconductor layer 4b is adopted. The electrode 10 is connected to the electrode 12b in the hole 26.

The hole 26 is also commonly referred to as contact hole. Since the hole 26 is opened in the termination region R2, the hole 26 can be referred to as termination region contact hole.

The electrode 12b does not achieve an ohmic junction between the semiconductor layer 13b and the electrode 10, and does not connect the semiconductor layers 13b, 4b. For example, in plan view, the hole 26 is located in a region occupied by the semiconductor layer 4b, and the electrode 12b is not adjacent to the semiconductor layer 13b.

The range in which the semiconductor layer 4b is formed in the direction Y in the cross section viewed in the direction X is not necessarily over the entire semiconductor layer 13b, and may be partial.

The semiconductor layer 13b contributes to the mitigation of the electric field applied to the insulating layer 6b at a position where the insulating layer 6b is bent between the direction Y and the direction Z when viewed in the direction X.

The hole 25 is opened in the interlayer insulating film 8a in the termination region R2. A part of the conductive layer 7b is exposed from the interlayer insulating film 8a in the hole 25.

The gate wiring 21 partially covers the interlayer insulating film 8a in the termination region R2, and is connected to the conductive layer 7b in the hole 25. The conductive layer 7a is electrically connected to the gate pad 24 via the gate wiring 21 and the conductive layer 7b, and functions as a gate electrode.

The hole 25 is also commonly referred to as contact hole. Since the hole 25 is involved in the connection between the gate wiring 21 and the conductive layer 7b, the hole 25 may be referred to as gate contact hole.

The semiconductor device 200 includes the termination structure 22 in the termination region R2. The termination structure 22 is located on the side opposite to the semiconductor layer 3a with respect to the semiconductor layer 13b. For example, the termination structure 22 is adjacent to the semiconductor layer 13b. For example, similarly to the semiconductor device 100, a structure commonly referred to as JTE, a structure commonly referred to as FLR, or a structure combining JTE and FLR is adopted as the termination structure 22.

The termination structure 22 is adjacent to the surface 2t. The surface 2t protrudes to the side opposite to the surface 2s (the direction opposite to the direction Z according to FIG. 8) on the side opposite to the semiconductor layer 4b (the direction Y side according to FIG. 8) with respect to the termination structure 22. The field insulating film 8b, the insulating layer 6b, and the interlayer insulating film 8a are also bent by reflecting the protrusion.

In the termination region R2, the semiconductor layers 4b, 13b, the insulating layer 6b, the conductive layer 7b, and the termination structure 22 are arranged at the concave portion of the surface 2t. Such a concave portion is illustrated in FIG. 8 as an external trench TO.

The semiconductor device 200 includes the protective insulating film 23. The protective insulating film 23 covers the electrode 10, the interlayer insulating film 8a, and at least a part of the gate wiring 21 from the side opposite to the semiconductor layer 2 in the termination region R2. FIG. 8 illustrates a state in which the entire gate wiring 21 is covered with the protective insulating film 23.

### <6-2. Concentration Distribution of Recombination Centers>

Also in the semiconductor device 200, recombination centers are introduced similarly to the semiconductor device 100. The recombination centers are included in the semiconductor layer 2, for example. For example, recombination centers are introduced into the semiconductor layer 2 by implantation of protons or helium.

FIG. 9 also illustrates the distribution Q5 of the concentration Cr of recombination centers in the direction Z. In FIGS. 8 and 9, the position LK where the concentration Cr exhibits the local maximum Cp, which is the concentration peak in the distribution Q5, is indicated.

Referring to FIG. 9, the concentration Cr has the distribution Q5 between the value Cd and the local maximum Cp. For example, the value Cd serves as a baseline for the concentration Cr.

The position LK is between the surfaces 2s, 2t and is separated from the surface 2s. The position LK is between the surface 2s side end of the insulated gate TG and the surface 2s.

Similarly to the semiconductor device 100, the semiconductor layer 2 is divided into the region S1 extending from the position B1 to the position B2 and the region S2 extending from the position B2 to the position B3. FIG. 8 illustrates a case where the position LK and the surface 2s are independent of the direction Y.

In the semiconductor device 200, the position B1 is, for example, a position closer to the surface 2s between a position in the direction Z of the end on the surface 2s side of the semiconductor layer 13a and a position in the direction Z of the end on the surface 2s side of the semiconductor layer 13b.

FIG. 8 illustrates a case where both positions are equivalent and the position in the direction Z of the end on the surface 2s side of the semiconductor layer 13b is adopted as the position B1. In this case, similarly to the semiconductor device 100, the position B1 can be said to be a position in the direction Z of the bottom of the concave portion of the surface 2t.

Similarly to the semiconductor device 100, the position B2 is a position in the direction Z of the position LK. The position B3 is a position in the direction Z of the surface 2s.

Also in the semiconductor device 200, a local maximum appears in the concentration of recombination centers at the position B2 away from the surface 2s. Therefore, even if the stacking faults expand in the epitaxial layer due to the application of the current, the range of the expansion is limited to only one of the regions S1 and S2, and the area of the stacking faults which expand is reduced as compared with conventional cases.

According to FIG. 9, as described below, the end of the semiconductor layer 4a on the side opposite to the semiconductor layer 2 and the end of the semiconductor layer 5a on the side opposite to the semiconductor layer 2 are at the same position in the direction Z, and the position is set as a reference position in the direction Z. For simplicity, it is assumed that the position in the direction Z of the end of the insulating layer 6t on the surface 2s side coincides with the position in the direction Z of the end of the semiconductor layer 13b on the surface 2s side.

A following inequality (9) is expressed by introducing a thickness D1 of the insulated gate TG in the direction Z (also referred to as distance from the reference position of the position B1 in the above assumption), the thickness S of the semiconductor layer 2 from the surface 2s to the insulated gate TG in the direction Z, and the distance Dp from the reference position (also referred to as distance from the reference position of the position B2). The local maximum Cp appears in the distribution Q5 at the distance Dp satisfying the inequality. In this case, the position LK is at the distance Dp from the reference position.

$$D 1 / Dp < D 1 + S \qquad ( 9 )$$

When the concentration Cr is not considered, the stacking faults may extend in the semiconductor layer 2 from the surface 2s to the insulated gate TG or the external trench TO. As described above, even if the stacking faults expand in the semiconductor layer 2 due to the application of the current, the range of the expansion is limited to only one of the regions S1 and S2.

Therefore, when the distance Dp satisfies a following formula (10) (at this time, the inequality (9) is always satisfied), the range in which the stacking faults expand does not exceed half of the range in the case where recombination centers are not introduced. When the distance Dp satisfies the following formula (10), the effect of suppressing the expansion of the stacking faults is higher compared to cases when the distance Dp does not satisfy the following formula (10) even if the inequality (9) is satisfied.

$$Dp = D 1 + ( 1 / 2 ) S \qquad ( 10 )$$

It can be said that when the formula (10) is satisfied, the local maximum Cp appears in the distribution Q5 at the center in the direction Z between the surface 2s and the insulated gate TG or the external trench TO.

Also in the semiconductor device 200, similarly to the semiconductor device 101 (see FIG. 4), the concentration Cr can take a local maximum at a plurality of positions in the direction Z. For example, when the number of the positions is n and the positions are at the distances Dp1, Dp2, . . . , and Dpn from the reference position in the direction Z, respectively, a following formula (11) is satisfied by introducing an integer r of 1 or more and n or less and replacing the thickness D0 with the thickness D1 in the formula (5). When the following formula (11) is satisfied, the effect of suppressing the expansion of the stacking faults is enhanced.

$$Dpr = D 1 + ( r / ( n + 1 ) ) S \qquad ( 11 )$$

Also in the semiconductor device 200, as exemplified by the semiconductor device 102 (see FIG. 5), the concentration Cr may have a local maximum on the surface 2s. Also in the semiconductor device 200, as exemplified by the semiconductor device 103 (see FIG. 6) and the semiconductor device 104 (see FIG. 7), the semiconductor layer 9 as a boundary layer or a buffer layer may be provided. In these cases, the formulae (6) to (8) for the semiconductor device 200 can be applied by replacing the thickness D0 with the thickness D1.

### 7. Seventh Preferred Embodiment

In the seventh preferred embodiment, a pillar region is introduced. The pillar region contributes to the improvement of depletion in the drift layer and, consequently, to the enhancement of the breakdown voltage of the semiconductor device.

### <7-1. Modification to Planar Insulated Gate Field Effect Transistor>

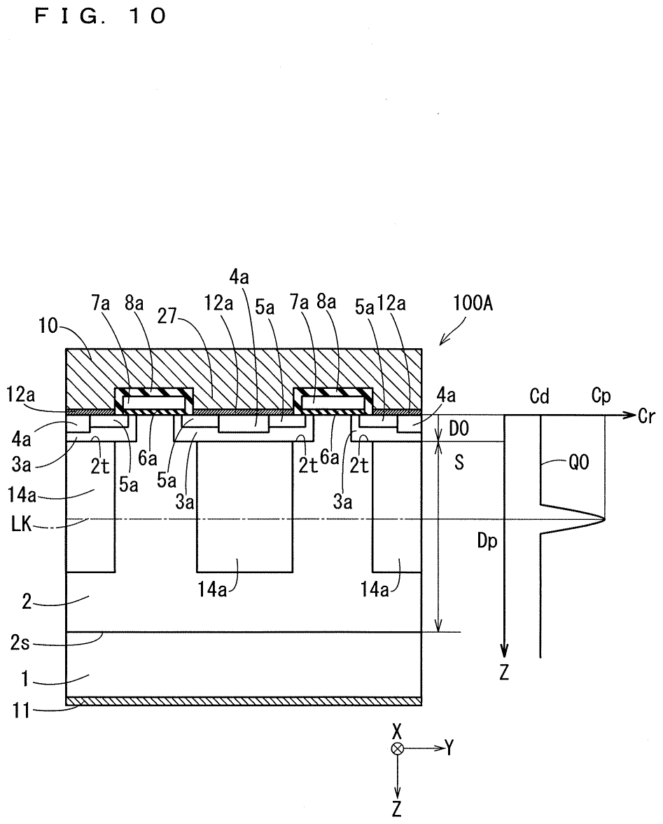

FIG. 10 is a cross-sectional view schematically illustrating a semiconductor device 100A in a part of the active region R1. The cross section is viewed in the direction X. The cross section may appear as viewed in the direction Y. FIG. 10 also schematically illustrates the distribution Q0 in the direction Z of the concentration Cr of recombination centers.

The semiconductor device 100A is a modification of the semiconductor device 100 described with reference to FIG. 3. Specifically, the semiconductor device 100A has a configuration in which a part of the semiconductor layer 2 is replaced with a semiconductor layer 14a compared to the semiconductor device 100.

The semiconductor layer 14a is arranged in contact with the end of the semiconductor layer 3a on the surface 2s side. The semiconductor layer 14a is arranged to extend in the direction Z from the end toward the surface 2s. It can be said that the semiconductor layer 14a is adjacent to the semiconductor layer 3a and extends toward the surface 2s. The semiconductor layer 14a may be separated from the substrate 1 or may penetrate the semiconductor layer 2 to reach the substrate 1.

The conductivity type of the semiconductor layer 14a is the same as the conductivity type of the semiconductor layer 3a, and is opposite to the conductivity type of the semiconductor layer 2. For example, the semiconductor layer 14a is made of a p-type silicon carbide.

The semiconductor layer 14a performs a function which is commonly referred to as pillar region in a so-called super junction structure. The semiconductor layers 14a arranged in the direction Y improve depletion in the semiconductor layer 2 sandwiched therebetween, thereby contributing to improvement of the breakdown voltage of the semiconductor device 100A.

Also in the semiconductor device 100A, similarly to the semiconductor device 100, the distribution Q0 of the concentration Cr has the local maximum Cp, thereby contributing to reducing the area of the stacking faults which expand.

As exemplified by the semiconductor device 101 (see FIG. 4), the semiconductor layer 14a can also be adopted in a case where the concentration Cr exhibits the distribution Q1 and has a plurality of local maxima. As exemplified by the semiconductor device 102 (see FIG. 5), the semiconductor layer 14a can also be adopted in a case where the concentration Cr has a local maximum on the surface 2s. As exemplified by the semiconductor device 103 (see FIG. 6) and the semiconductor device 104 (see FIG. 7), the semiconductor layer 14a can also be adopted in a case where the semiconductor layer 9 as a boundary layer or a buffer layer is provided. In this case, the semiconductor layer 14a is not in contact with the semiconductor layer 9 or is in contact with the semiconductor layer 9 on the side opposite to the semiconductor layer 2.

Even if the semiconductor layer 14a is introduced into any of the semiconductor devices 100, 101, 102, 103, 104, the function of recombination centers is maintained, and the breakdown voltage is improved by the introduction of the semiconductor layer 14a.

### <7-2. Modification to Trench-Type Insulated Gate Field Effect Transistor>

### <7-2-1. First Modification to Semiconductor Device 200>

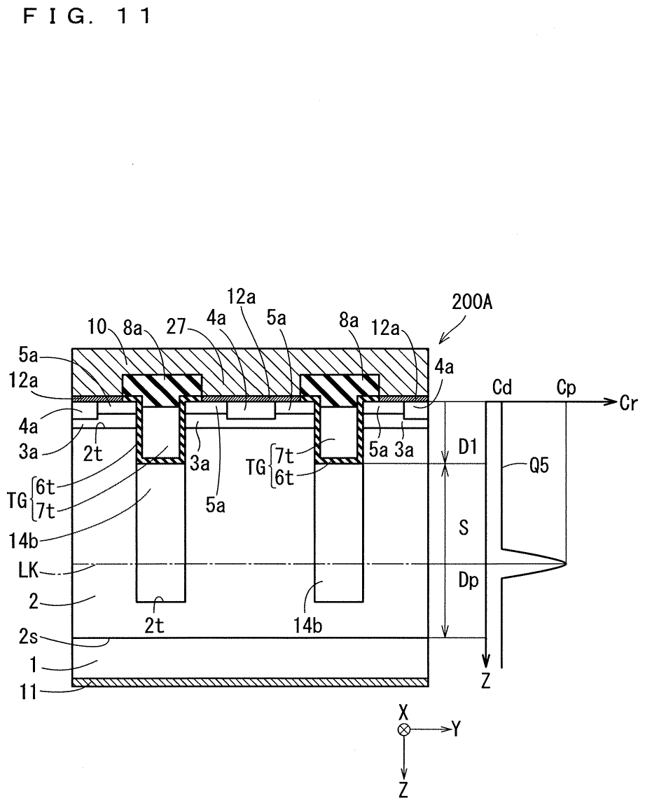

FIG. 11 is a cross-sectional view schematically illustrating a semiconductor device 200A in a part of the active region R1. The cross section is viewed in the direction X. The cross section may appear as viewed in the direction Y. FIG. 11 also schematically illustrates the distribution Q5 in the direction Z of the concentration Cr of recombination centers.

The semiconductor device 200A is a modification of the semiconductor device 200 described with reference to FIG. 9. The semiconductor device 200A has a configuration in which the semiconductor layer 13a is omitted and the semiconductor layer 14b is used compared to the semiconductor device 200 (see FIG. 9).

Similarly to semiconductor layer 14a (see FIG. 10) in the semiconductor device 100A, the semiconductor layer 14b is arranged in contact with the end of semiconductor layer 3a on the surface 2s side. For example, the semiconductor layer 14b is arranged adjacent to the insulated gate TG in the direction X. On the cross section illustrated in FIG. 11, the semiconductor layer 14b also appears on the surface 2s side of the insulated gate TG similarly to the semiconductor layer 13a.

The semiconductor layer 14b is arranged to extend in the direction Z from the end toward the surface 2s. It can be said that the semiconductor layer 14b is adjacent to the semiconductor layer 3a and extends toward the surface 2s. The semiconductor layer 14b may be separated from the substrate 1 or may penetrate the semiconductor layer 2 to reach the substrate 1.

The conductivity type of the semiconductor layer 14b is the same as the conductivity type of the semiconductor layers 3a, 13a, and is opposite to the conductivity type of the semiconductor layer 2. For example, the semiconductor layer 14b is made of a p-type silicon carbide. For example, the impurity concentration of the semiconductor layer 14b is lower than the impurity concentration of the semiconductor layer 13a.

The semiconductor layer 14b also performs a function commonly referred to as pillar region. The semiconductor layers 14b arranged in the direction Y improve depletion in the semiconductor layer 2 sandwiched therebetween, thereby contributing to improvement of the breakdown voltage of the semiconductor device 200A.

### <7-2-2. Second Modification to Semiconductor Device 200>

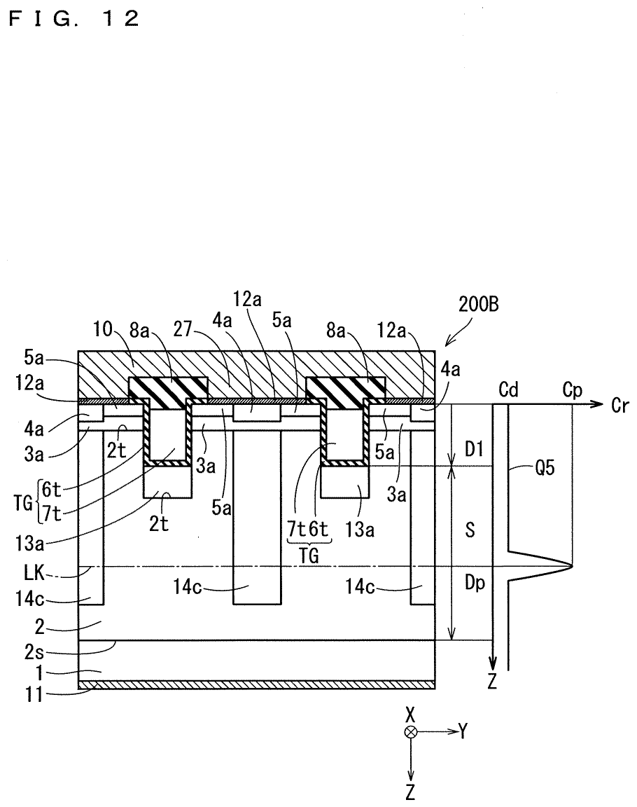

FIG. 12 is a cross-sectional view schematically illustrating a semiconductor device 200B in a part of the active region R1. The cross section is viewed in the direction X. The cross section may appear as viewed in the direction Y. FIG. 12 also schematically illustrates the distribution Q5 in the direction Z of the concentration Cr of recombination centers.

The semiconductor device 200B is a modification of the semiconductor device 200 described with reference to FIG. 9. Specifically, the semiconductor device 200B has a configuration in which a semiconductor layer 14c is added to the semiconductor device 200 (see FIG. 9).

The semiconductor layer 14c is arranged in contact with the end of the semiconductor layer 3a on the surface 2s side. The semiconductor layer 14c is arranged to extend in the direction Z from the end toward the surface 2s. It can be said that the semiconductor layer 14c is adjacent to the semiconductor layer 3a and extends toward the surface 2s. The semiconductor layer 14c may be separated from the substrate 1 or may penetrate the semiconductor layer 2 to reach the substrate 1.

The conductivity type of the semiconductor layer 14c is the same as the conductivity type of the semiconductor layer 3a, and is opposite to the conductivity type of the semiconductor layer 2. For example, the semiconductor layer 14c is made of a p-type silicon carbide. For example, the impurity concentration of the semiconductor layer 14c is lower than the impurity concentration of the semiconductor layer 13a.

The semiconductor layer 14c also performs a function commonly referred to as pillar region. The semiconductor layers 14c arranged in the direction Y improve depletion in the semiconductor layer 2 sandwiched therebetween, thereby contributing to improvement of the breakdown voltage of the semiconductor device 200B.

### <7-2-3. Third Modification to Semiconductor Device 200>

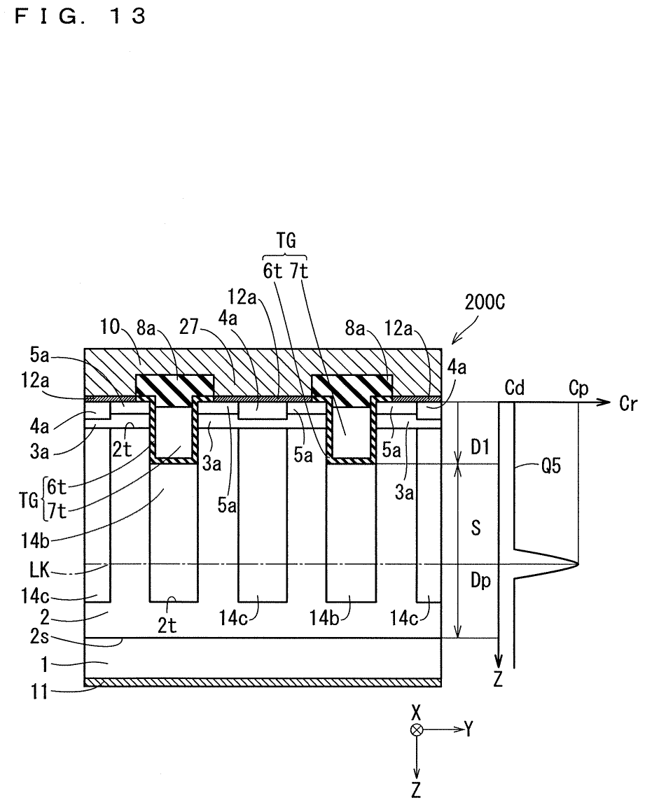

FIG. 13 is a cross-sectional view schematically illustrating a semiconductor device 200C in a part of the active region R1. The cross section is viewed in the direction X. The cross section may appear as viewed in the direction Y. FIG. 13 also schematically illustrates the distribution Q5 in the direction Z of the concentration Cr of recombination centers.

The semiconductor device 200C is a modification of the semiconductor device 200 described with reference to FIG. 9. Specifically, the semiconductor device 200C has a configuration in which the semiconductor layer 14c is added to the semiconductor device 200A (see FIG. 11). The semiconductor layer 14b and the semiconductor layer 14c arranged in the direction Y improve depletion in the semiconductor layer 2 sandwiched therebetween, thereby contributing to improvement of the breakdown voltage of the semiconductor device 200C.

Even if either or both of the semiconductor layers 14b, 14c are introduced into the semiconductor device 200, the function performed by recombination centers is maintained. In any of the semiconductor devices 200A, 200B, 200C, similarly to the semiconductor device 200, the distribution Q5 of the concentration Cr has the local maximum Cp, thereby contributing to reducing the area of the stacking faults which expand.

Either or both of the semiconductor layers 14b, 14c are introduced into the semiconductor device 200 to improve depletion of the semiconductor layer 2. In any of the semiconductor devices 200A, 200B, 200C, the device breakdown voltage is improved by improving depletion of the semiconductor layer 2.

As exemplified by the semiconductor device 101 (see FIG. 4), the concentration Cr may have a plurality of local maxima in the distribution Q5. As exemplified by the semiconductor device 102 (see FIG. 5), the concentration Cr may have a local maximum on the surface 2s.

As exemplified by the semiconductor device 103 (see FIG. 6) and the semiconductor device 104 (see FIG. 7), the semiconductor layer 14c may also be adopted in a case where the semiconductor layer 9 as a boundary layer or a buffer layer is provided. When the semiconductor layer 9 is provided, the semiconductor layers 14b, 14c are not in contact with the semiconductor layer 9 or are in contact with the semiconductor layer 9 on the side opposite to the semiconductor layer 2.

### 8. Eighth Preferred Embodiment

In the eighth preferred embodiment, a semiconductor device into which recombination centers are introduced other than the insulated gate field effect transistor having the above-described configuration is exemplified.

### <8-1. Incorporation of Schottky Barrier Diode>

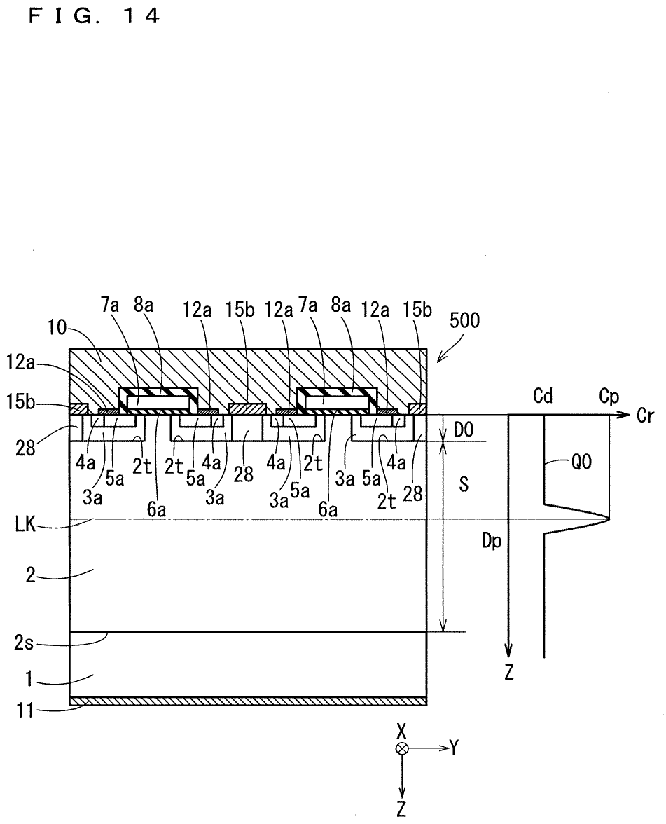

FIG. 14 is a cross-sectional view schematically illustrating a semiconductor device 500 in a part of the active region R1. The cross section is viewed in the direction X. The cross section may appear as viewed in the direction Y. FIG. 14 also schematically illustrates the distribution Q0 in the direction Z of the concentration Cr of recombination centers.

The semiconductor device 500 functions as an insulated gate field effect transistor incorporating a Schottky barrier diode. The semiconductor device 500 differs from the semiconductor device 100 (see FIG. 3) in the configuration between a pair of adjacent conductive layers 7a in a cross-sectional view (here, in a cross section viewed in the direction X).

Specifically, in the cross-sectional view, an electrode 15b and a pair of electrodes 12a sandwiching the electrode 15b are arranged between the pair of conductive layers 7a. Each of the electrodes 12a, 15b is covered with the electrode 10.

The semiconductor device 500 includes a semiconductor layer 28. The semiconductor layer 28 is arranged on the surface 2s side of the electrode 15b. For example, the electrode 15b faces at least the entire semiconductor layer 28 in plan view. A material that achieves a Schottky junction with the semiconductor layer 28 is adopted for the electrode 15b.

The semiconductor layer 28 is adjacent to the semiconductor layer 2 from the side opposite to the surface 2s. In the direction Z, the electrodes 10, 15b, the semiconductor layers 28, 2, the substrate 1, and the electrode 11 are arranged in this order. The semiconductor layer 28 faces the semiconductor layer 4a with the semiconductor layer 3a interposed therebetween. The semiconductor layer 5a faces the semiconductor layer 28 with the semiconductor layers 4a, 3a interposed therebetween.

The conductivity type of the semiconductor layer 28 is the same as the conductivity type of the semiconductor layer 2. For example, the semiconductor layer 28 is made of an n-type silicon carbide. The impurity concentration of the semiconductor layer 28 is higher than or equal to the impurity concentration of the semiconductor layer 2. The semiconductor layer 28 can also be regarded as a part of the semiconductor layer 2.

The substrate 1, the semiconductor layers 2, 28, and the electrode 15b are incorporated in the semiconductor device 500 and function as a Schottky barrier diode between a source and a drain.

Also in the semiconductor device 500, similarly to the semiconductor device 100, the thicknesses D0 and S are introduced, and the local maximum Cp appears in the distribution Q0 at the distance Dp satisfying the inequality (1). For example, the distance Dp satisfies the formula (2). Also in the semiconductor device 500, similarly to the semiconductor device 100, the area of the stacking faults, which expand, is reduced.

As exemplified by the semiconductor device 101 (see FIG. 4), the concentration Cr may have a plurality of local maxima in the distribution Q0. As exemplified by the semiconductor device 102 (see FIG. 5), the concentration Cr may have a local maximum on the surface 2s. As exemplified by the semiconductor device 103 (see FIG. 6) and the semiconductor device 104 (see FIG. 7), the semiconductor layer 9 as a boundary layer or a buffer layer may be provided.

### <8-2. Insulated Gate Bipolar Transistor>

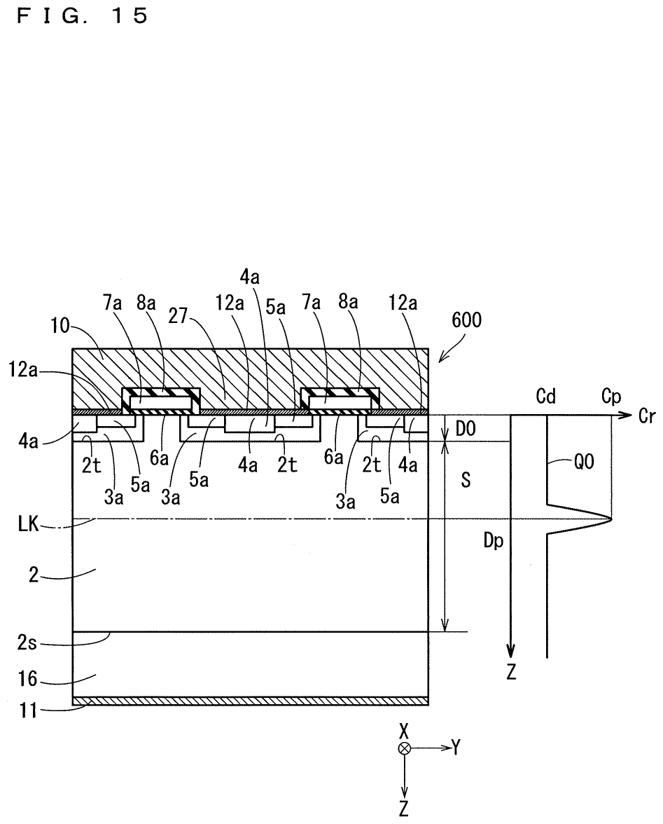

FIG. 15 is a cross-sectional view schematically illustrating a semiconductor device 600 in a part of the active region R1. The cross section is viewed in the direction X. The cross section may appear as viewed in the direction Y. FIG. 15 also schematically illustrates the distribution Q0 in the direction Z of the concentration Cr of recombination centers.

The semiconductor device 600 functions as an insulated gate bipolar transistor. The semiconductor device 600 has a configuration in which the substrate 1 of the semiconductor device 100 (see FIG. 3) is replaced with a semiconductor layer 16. The conductivity type of the semiconductor layer 16 is opposite to the conductivity type of the semiconductor layer 2. For example, the semiconductor layer 16 is made of a p-type silicon carbide.

In the semiconductor device 600, the electrode 10 functions as an emitter electrode, and the electrode 11 functions as a collector electrode.

Also in the semiconductor device 600, similarly to the semiconductor device 100, the thicknesses D0 and S are introduced, and the local maximum Cp appears in the distribution Q0 at the distance Dp satisfying the inequality (1). For example, the distance Dp satisfies the formula (2). Also in the semiconductor device 600, similarly to the semiconductor device 100, the area of the stacking faults, which expand, is reduced.

As exemplified by the semiconductor device 101 (see FIG. 4), the concentration Cr may have a plurality of local maxima in the distribution Q0. As exemplified by the semiconductor device 102 (see FIG. 5), the concentration Cr may have a local maximum on the surface 2s.

### <8-3. Schottky Barrier Diode>

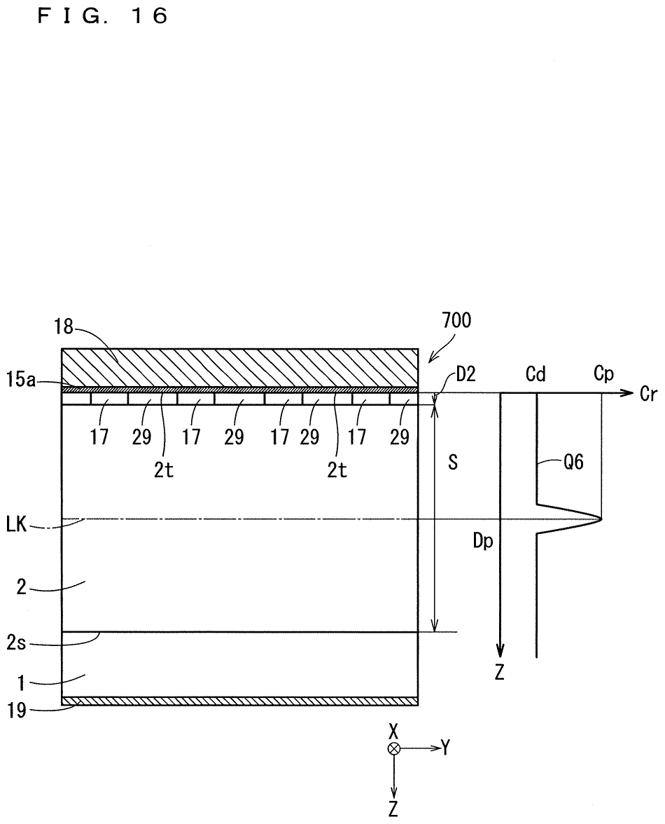

FIG. 16 is a cross-sectional view schematically illustrating a semiconductor device 700 in a part of the active region R1. The cross section is viewed in the direction X. The cross section may appear as viewed in the direction Y. FIG. 16 also schematically illustrates a distribution Q6 in the direction Z of the concentration Cr of recombination centers.

The semiconductor device 700 functions as a Schottky barrier diode. The semiconductor device 700 includes the substrate 1, the semiconductor layer 2 and a semiconductor layer 17. For example, the semiconductor layer 2 is a so-called epitaxial layer formed by epitaxial growth on the substrate 1.

Similarly to the semiconductor device 100 (see FIG. 3), the semiconductor layer 2 has the surfaces 2s, 2t. The surface 2s is adjacent to the substrate 1. The surface 2t faces the surface 2s in the direction Z. For example, the surface 2s is flat, and the surface 2t has irregularities. A part which is the convex portion of the semiconductor layer 2 can be recognized as a semiconductor layer 29. For example, the substrate 1 is made of an n-type low-resistance silicon carbide, and the semiconductor layer 2 is made of an n-type silicon carbide having a resistivity higher than that of the substrate 1.

The semiconductor layer 17 is adjacent to the semiconductor layer 2 from the side opposite to the surface 2s. The semiconductor layer 17 is adjacent to the surface 2t at the concave portion of the semiconductor layer 2. When the convex portion of the semiconductor layer 2 is recognized as the semiconductor layer 29, the semiconductor layer 29 separates the semiconductor layer 17.

The semiconductor device 700 includes electrodes 15a, 18. The electrode 15a is adjacent to the semiconductor layer 17 and the semiconductor layer 29 from the side opposite to the semiconductor layer 2. It can also be said that the electrode 15a is adjacent to the surface 2t in a region other than the region where the semiconductor layer 17 is provided.

The conductivity type of the semiconductor layer 17 is opposite to the conductivity type of the semiconductor layers 2, 29. For example, the semiconductor layer 17 is made of a p-type silicon carbide. A material that achieves a Schottky junction with the semiconductor layer 29 is adopted for the electrode 15a.

The electrode 18 is adjacent to the electrode 15a from the side opposite to the semiconductor layer 2. The electrode 18 faces the semiconductor layer 17 and the semiconductor layer 29 with the electrode 15a interposed therebetween. For the electrode 18, a material that achieves an ohmic junction with the electrode 15a is adopted.

The semiconductor device 700 includes an electrode 19. The electrode 19 is adjacent to the substrate 1 from the side opposite to the semiconductor layer 2. In the direction Z, the electrodes 18, 15a, the semiconductor layers 29, 2, the substrate 1, and the electrode 19 are arranged in this order, or the electrodes 18, 15a, the semiconductor layers 17, 2, the substrate 1, and the electrode 19 are arranged in this order. For example, the electrode 18 functions as an anode electrode, and the electrode 19 functions as a cathode electrode.

Similarly to the semiconductor device 100, in the semiconductor device 700, a following inequality (12) is expressed by introducing a thickness D2 of the semiconductor layer 17 in the direction Z, the thickness S of the semiconductor layer 2 from the surface 2s to the semiconductor layer 3a in the direction Z, and the distance Dp from the reference position (also referred to as distance from the reference position of the position B2). Also in the semiconductor device 700, similarly to the semiconductor device 100, the area of the stacking faults, which expand, is reduced.

$$D 2 < D p < D 2 + S \qquad ( 12 )$$

For example, in the formula (10), the thickness D0 is replaced with the thickness D2, and the distance Dp satisfies a formula (13). At this time, the effect of suppressing the expansion of the stacking faults is enhanced.

$$D p = D 2 + ( 1 / 2 ) S \qquad ( 13 )$$

As exemplified by the semiconductor device 101 (see FIG. 4), the concentration Cr may have a plurality of local maxima in the distribution Q6. As exemplified by the semiconductor device 102 (see FIG. 5), the concentration Cr may have a local maximum on the surface 2s. As exemplified by the semiconductor device 103 (see FIG. 6) and the semiconductor device 104 (see FIG. 7), the semiconductor layer 9 as a boundary layer or a buffer layer may be provided.

### 9. Ninth Preferred Embodiment

In the ninth preferred embodiment, various modes are exemplified for the range in plan view into which recombination centers are introduced.

### <9-1. Introduction of Recombination Centers Across Entirety in Plan View>

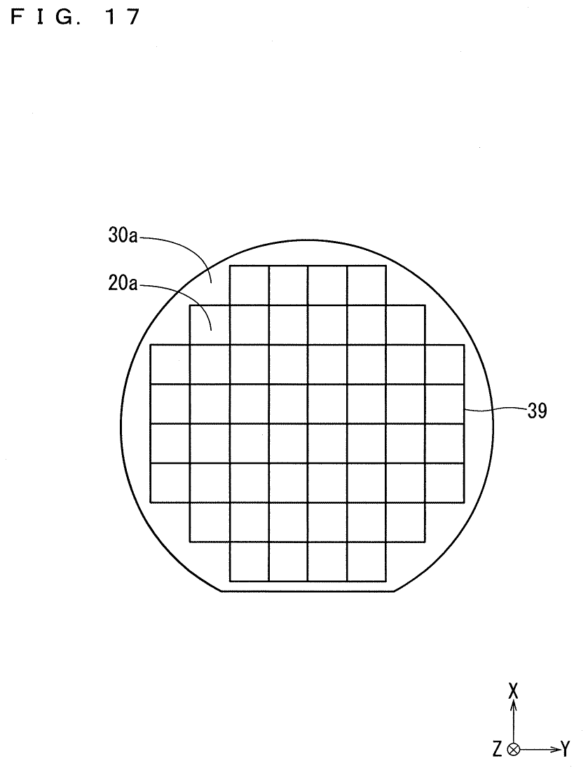

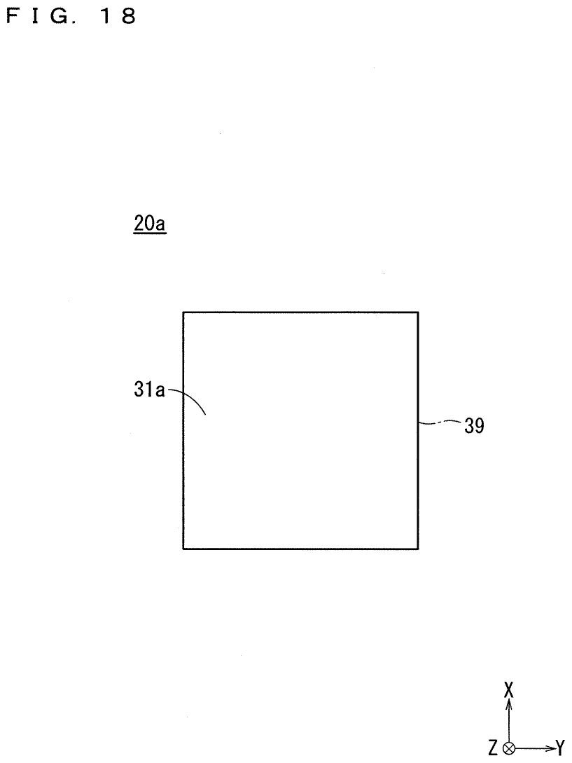

FIG. 17 is a plan view schematically illustrating a wafer 30a and a die 20a. FIG. 18 is a plan view schematically illustrating one die 20a.

The die 20a can be used for manufacturing the semiconductor devices 100, 101, 102, 103, 104, 100A, 200, 200A, 200B, 200C, 500, 600, 700. The wafer 30a is, for example, a so-called epitaxial wafer on which the substrate 1 and the semiconductor layer 2 are provided. For example, in the manufacture of the semiconductor device 600, p-type impurities are introduced into the substrate 1 to obtain the semiconductor layer 16.

The wafer 30a is cut along dicing lines 39 to obtain the die 20a. Here, a case where the dicing lines 39 have a lattice shape and the die 20a has a rectangular shape in plan view is exemplified. In plan view, all the dies 20a are adjacent to each other without overlapping on the wafer 30a. The outer edges of the die 20a correspond to the dicing lines 39 before the wafer 30a is cut.

FIG. 18 illustrates a region 31a into which recombination centers are introduced. For example, recombination centers are introduced into the entire wafer 30a in plan view. In this case, the region 31a is introduced into the entire die 20a in plan view.

<9-2. Avoidance of Introduction into Dicing Lines>

Recombination centers do not need to be introduced over the entire semiconductor layer 2 in plan view. For example, substantially no functioning semiconductor devices are formed on the dicing lines 39. It is not necessary to introduce recombination centers into the dicing lines 39.

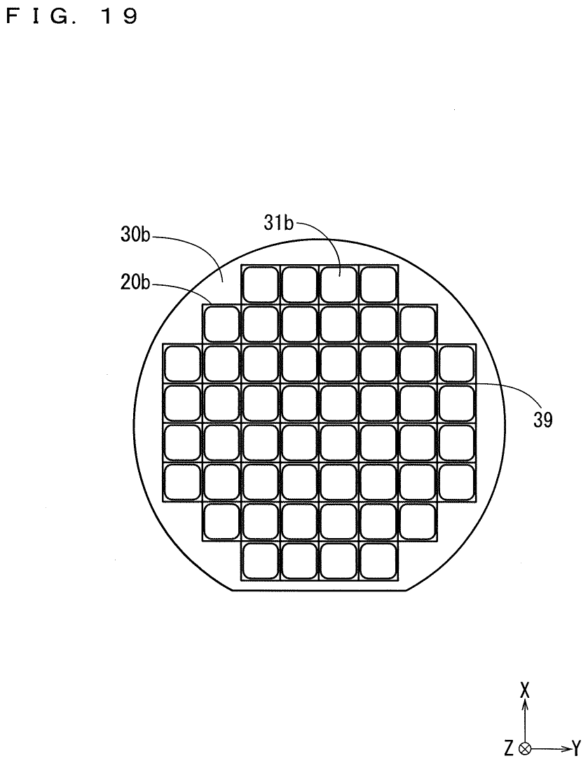

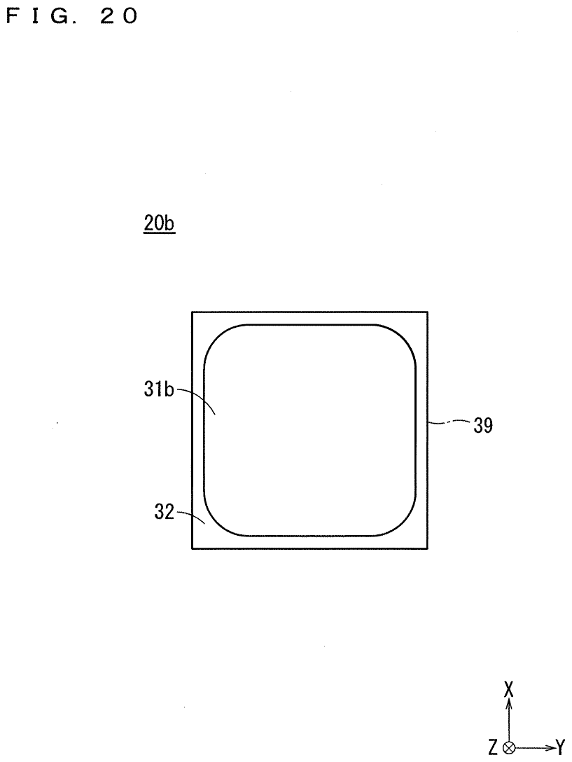

FIG. 19 is a plan view schematically illustrating a wafer 30b and a die 20b. FIG. 20 is a plan view schematically illustrating one die 20b.

The die 20b can be used for manufacturing the semiconductor devices 100, 101, 102, 103, 104, 100A, 200, 200A, 200B, 200C, 500, 600, 700. The wafer 30b is, for example, a so-called epitaxial wafer on which the substrate 1 and the semiconductor layer 2 are provided. For example, in the manufacture of the semiconductor device 600, p-type impurities are introduced into the substrate 1 to obtain the semiconductor layer 16.

The wafer 30b is cut along the dicing lines 39 to obtain the die 20b. Here, a case where the dicing lines 39 have a lattice shape and the die 20b has a rectangular shape in plan view is exemplified. In plan view, all the dies 20b are adjacent to each other without overlapping on the wafer 30b. The outer edges of the die 20b correspond to the dicing lines 39 before the wafer 30b is cut.

FIGS. 19 and 20 illustrate a region 31b into which recombination centers are introduced. For example, recombination centers are introduced into the wafer 30b while avoiding the dicing lines 39 and the vicinity thereof in plan view. In this case, a region 32 where the introduction of recombination centers is avoided is in the vicinity of the outer edges of the die 20b surrounding the region 31b in the die 20b.

No main current flows in the region 32, and suppression of growth of crystal defects in the semiconductor layer 2 is not emphasized in the region 32. Therefore, recombination centers do not need to be introduced into the region 32.

Here, the “main current” refers to a current flowing between the surfaces 2s, 2t in the semiconductor layer 2. For example, in the cases of the semiconductor devices 100, 101, 102, 103, 104, 100A, 200, 200A, 200B, 200C, 500, the “main current” refers to a so-called drain current flowing between the electrodes 10, 11. For example, in the case of the semiconductor device 600, the “main current” refers to a so-called collector current flowing between the electrodes 10, 11. For example, in the case of the semiconductor device 700, the “main current” refers to a forward current flowing through the electrodes 18, 19.

Introduction of recombination centers into the wafer 30b, while avoiding the dicing lines 39 in the wafer 30b, for example, contributes to reduction of warpage of the wafer 30b due to introduction of recombination centers.

For example, implantation of protons or helium into the semiconductor layer 2 is exemplified as a method of introducing recombination centers. The implantation is performed prior to patterning of the semiconductor layer formed on the surface 2t side of the semiconductor layer 2, for example. By the implantation, the wafer 30b is less likely to warp than the wafer 30a, and the accuracy of the patterning is improved.

<9-3. Avoidance of Introduction into Termination Region R2>

### <9-3-1. Planar Insulated Gate Field Effect Transistor>

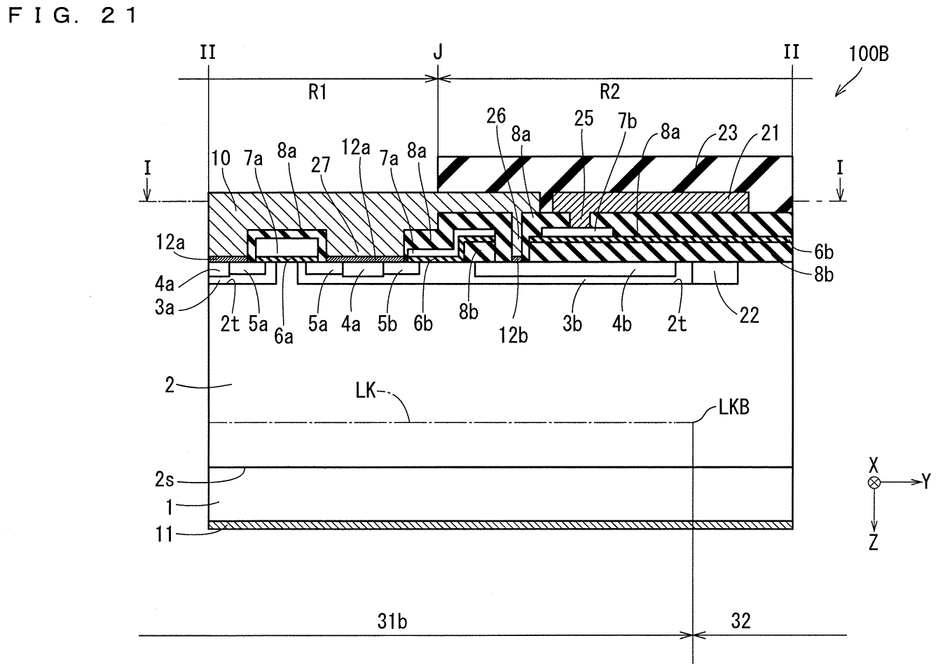

FIG. 21 is a cross-sectional view schematically illustrating the semiconductor device 100B. The semiconductor device 100B is a modification of the semiconductor device 100 described with reference to FIG. 2. Similarly to FIG. 2, FIG. 21 illustrates a cross section appearing at the position II-II in FIG. 1.

Specifically, the semiconductor device 100B is different from the semiconductor device 100 in that introduction of recombination centers is avoided in the region 32. The boundary between the region 31b into which recombination centers are introduced and the region 32 into which the introduction of recombination centers is avoided reflects a position of an end LKB of a chain line indicating the position LK.

Considering the range in which the above-described “main current” flows in the termination region R2, it is preferable that the region 31b extends to include the semiconductor layer 4b in plan view. The region 31b may extend to include the semiconductor layer 3b in plan view. The region 32 extends, for example, to include a range in which the termination structure 22 is provided in plan view. The region 32 may extend to the side opposite to the active region R1 (the direction Y side in FIG. 21) with respect to the termination structure 22.

It can be said that the concentration of recombination centers of the semiconductor layer 2 between the termination structure 22 and the surface 2s is lower than the local maximum of the concentration between the surface 2s and the surface 2t.

### <9-3-2. Trench-Type Insulated Gate Field Effect Transistor>

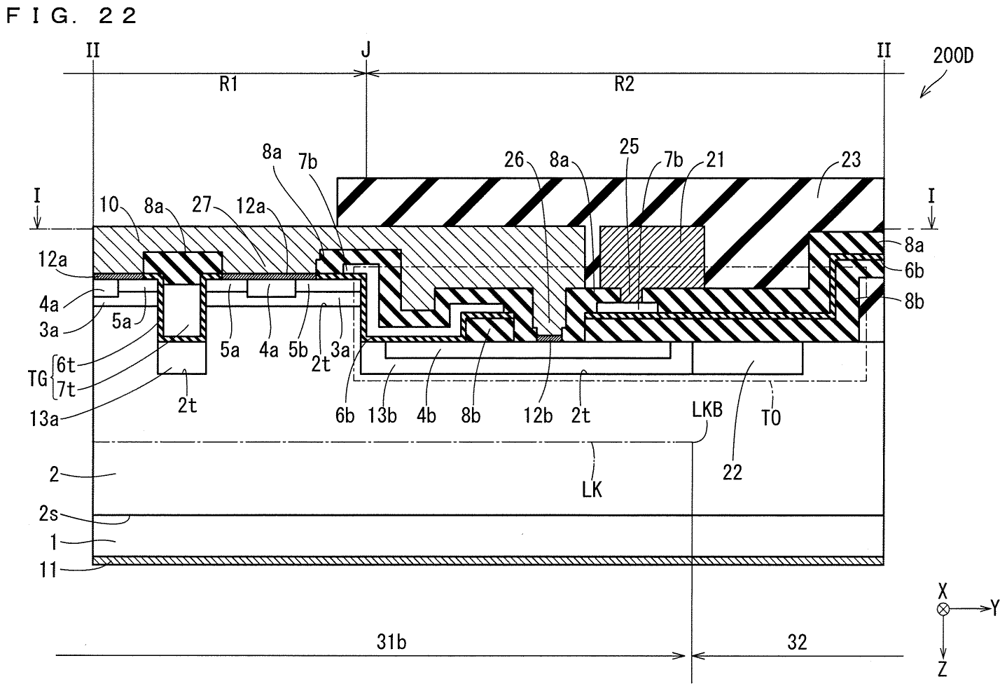

FIG. 22 is a cross-sectional view schematically illustrating the semiconductor device 200D. The semiconductor device 200D is a modification of the semiconductor device 200 described with reference to FIG. 8. Similarly to FIG. 8, FIG. 22 illustrates a cross section appearing at the position II-II in FIG. 1.

Specifically, the semiconductor device 200D is different from the semiconductor device 200 in that introduction of recombination centers is avoided in the region 32. The boundary between the region 31b into which recombination centers are introduced and the region 32 into which the introduction of recombination centers is avoided reflects the position of the end LKB of the chain line indicating the position LK.

Considering the range in which the above-described “main current” flows in the termination region R2, it is preferable that the region 31b extends to include the semiconductor layer 4b in plan view. The region 31b may extend to include the semiconductor layer 13b in plan view. The region 32 extends, for example, to include a range in which the termination structure 22 is provided in plan view. The region 32 may extend to the side opposite to the active region R1 (the direction Y side in FIG. 22) with respect to the termination structure 22.

It can be said that the concentration of recombination centers of the semiconductor layer 2 between the termination structure 22 and the surface 2s is lower than the local maximum of the concentration between the surface 2s and the surface 2t.

In both the semiconductor devices 100B, 200D, a plurality of positions LK may exist in the direction Z as in the third preferred embodiment. For example, the ends LKB corresponding to the plurality of positions LK coincide with each other in plan view.

### 10. Modification of Termination Region R2

In view of the ninth preferred embodiment, in the region 32, a semiconductor element of a different type from the semiconductor device 100B can be formed in the region 32 together with the semiconductor device 100B (see FIG. 21).

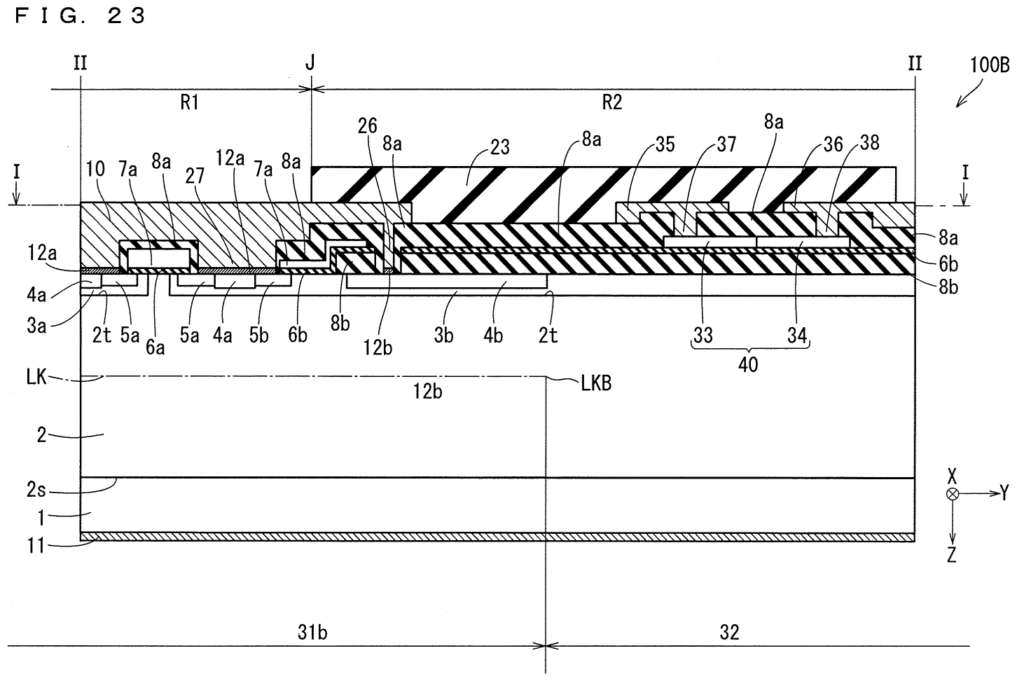

FIG. 23 is a cross-sectional view illustrating a cross section at a position corresponding to FIG. 21. FIG. 23 illustrates a structure in which a semiconductor element 40 is provided in the region 32. The region 31b extends to include the semiconductor layer 4b in plan view. The semiconductor element 40 is, for example, a temperature sensor diode.

FIG. 23 illustrates a case where the semiconductor layer 3b also extends in the region 32. In the region 32, the insulating layer 6b, the field insulating film 8b, the semiconductor layer 3b, the semiconductor layer 2, and the substrate 1 are arranged in this order in the direction Z.

The semiconductor element 40 has an anode region 33 and a cathode region 34. The anode region 33 and the cathode region 34 are both adjacent to the insulating layer 6b in the region 32 on the side opposite to the semiconductor layer 2. The anode region 33 and the cathode region 34 are arranged adjacent to each other. The anode region 33 and the cathode region 34 form a so-called pn junction. For example, the anode region 33 is made of a p-type doped polysilicon, and the cathode region 34 is made of an n-type doped polysilicon.

Holes 37, 38 are opened in the interlayer insulating film 8a. The anode region 33 is exposed from the interlayer insulating film 8a in the hole 37. The cathode region 34 is exposed from the interlayer insulating film 8a in the hole 38.

Electrodes 35, 36 are adjacent to the interlayer insulating film 8a on the side opposite to the semiconductor layer 2. The electrode 35 is adjacent to the anode region 33 in the hole 37. For the electrode 35, a material that achieves an ohmic junction with the anode region 33 is adopted. The electrode 36 is adjacent to the cathode region 34 in the hole 38. For the electrode 36, a material that achieves an ohmic junction with the cathode region 34 is adopted. For example, at least a part of the electrodes 35, 36 is covered with the protective insulating film 23.

Similarly to the above, a semiconductor element of a different type from the semiconductor device 200D can be formed in the region 32 together with the semiconductor device 200D (see FIG. 22).

Also in the modifications illustrated in FIGS. 22 and 23, as described in the ninth preferred embodiment, a plurality of positions LK may exist in the direction Z. For example, the ends LKB corresponding to the plurality of positions LK coincide with each other in plan view.

Another example of the above-described “semiconductor element of a different type” is a current sense (not illustrated). The current sense is a control pad for detecting a current flowing through a cell region of the semiconductor device. The current sense is electrically connected to cells in an active region of a part of the cell region such that when a current flows in the cell region of the semiconductor device, a current ranging from a fraction to tens of thousandths of the total current flowing through the entire cell region flows through the current sense.

The current sense may be provided in the region 31b. In the region 31b, recombination centers are introduced. The recombination centers reduce expansion of the area of the stacking faults as described in the above-described preferred embodiments and modifications. Providing the current sense in the region 31b reduces the influence of the area of the stacking faults on the current sense and contributes to improving the measurement accuracy of the current sense.

The gate pad 24 may be provided in the region 31b. Providing the gate pad 24 in the region 31b reduces the influence of the area of the stacking faults on the gate pad 24, and contributes to improving the accuracy of controlling the semiconductor device by the gate voltage.

### 11. Tenth Preferred Embodiment

In the tenth preferred embodiment, a method of introducing recombination centers into the semiconductor layer 2 is exemplified. For simplification of description, a case where the semiconductor layer 2 is obtained by epitaxial growth on the substrate 1 and is adjacent to the substrate 1 is exemplified (see FIGS. 2 to 5, FIGS. 8 to 14, and FIG. 16). Here, it is obvious that the method can also be applied to a case where the semiconductor layer 9 is provided between the substrate 1 and the semiconductor layer 2 (see FIGS. 6 and 7) or a case where the semiconductor layer 16 is adopted instead of the substrate 1 (see FIG. 15).

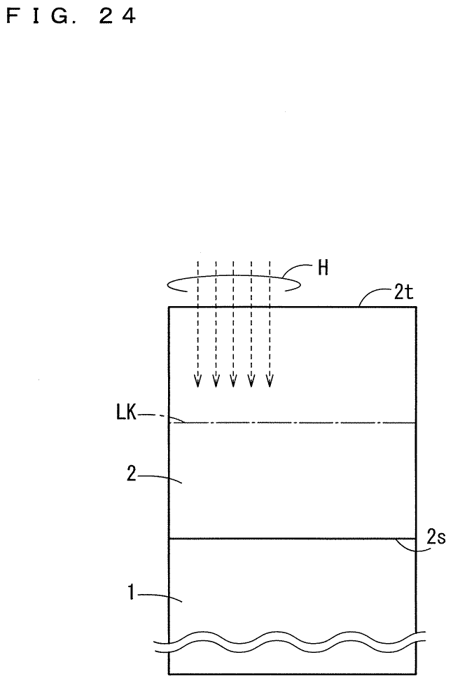

FIG. 24 is a cross-sectional view schematically illustrating a first example of the tenth preferred embodiment. In the first example, protons or helium (hereinafter, these are collectively referred to as “particles H”) is implanted from the semiconductor layer 2 side (surface 2t) into the stacked structure of the substrate 1 and the semiconductor layer 2. In the first example, the particles H are implanted into the semiconductor layer 2 in a direction from the surface 2t toward the surface 2s.

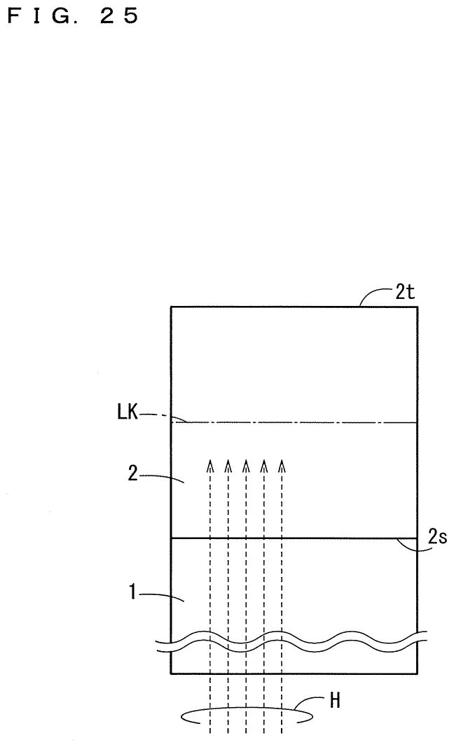

FIG. 25 is a cross-sectional view schematically illustrating a second example of the tenth preferred embodiment. In the second example, the particles H are implanted from the substrate 1 side into the stacked structure of the substrate 1 and the semiconductor layer 2. In the second example, the particles H are implanted into the semiconductor layer 2 in a direction from the surface 2s toward the surface 2t.

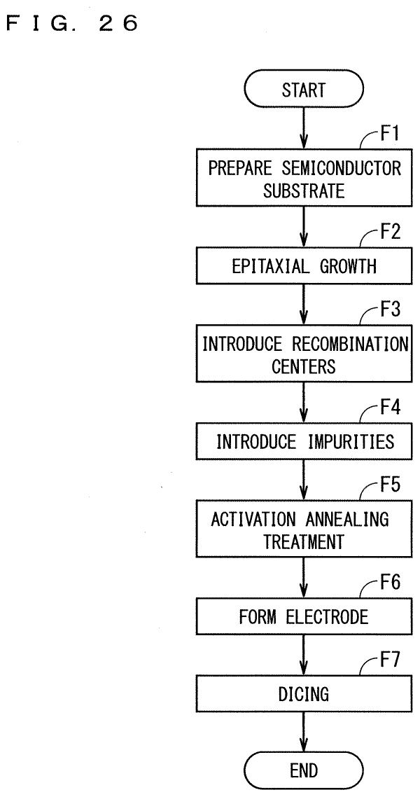

FIG. 26 is a flowchart illustrating an outline of steps of manufacturing various semiconductor devices according to the present disclosure. The flowchart includes steps F1 to F7.

Step F1 is a step of preparing a semiconductor substrate. For example, the substrate 1 made of an n-type silicon carbide is adopted as the semiconductor substrate. Step F2 is a step of obtaining the semiconductor layer 2 or the semiconductor layers 2, 9 as epitaxial layers by epitaxial growth on the substrate 1. When the substrate 1 is made of an n-type silicon carbide, the semiconductor layers 2, 9 are epitaxial layers made of an n-type silicon carbide, for example.

After step F2 is completed to obtain the epitaxial layer, step F3 is performed. Step F3 is a step of introducing recombination centers. In step F3, for example, either method or both methods of the first example (FIG. 24) and the second example (FIG. 25) are adopted.

Step F4 is a step of introducing impurities into the semiconductor layer 2. For example, p-type or n-type impurities are introduced into the surface 2t. The region into which the impurities are implanted is also commonly referred to as “implantation layer”. Step F5 is a step of performing annealing which is a treatment for activating the impurities introduced in step F4 (abbreviated as “activation annealing treatment” in FIG. 26). By step F5, for example, the semiconductor layers 3a, 3b, 4a, 4b, 5a, 5b are obtained from the implantation layer. Step F5 is performed after step F3 is completed. It is preferable that recombination centers are introduced prior to the implantation of the impurities, and thus, it is preferable that step F4 is performed after step F3 is completed.

Step F6 is a step of forming an electrode. The electrode may also have a planar insulated gate or a trench-type insulated gate in addition to the electrodes 10, 11, 12a, 12b, 15a, 15b, 18, 19, 35, 36. Step F7 is a step of performing dicing. In step F7, for example, dicing is performed along the dicing lines 39 (see FIGS. 17 and 19), and the dies 20a, 20b are obtained (see FIGS. 18 and 20).

According to the method of the second example, defects caused by implantation (hereinafter, “implantation defects”) are less likely to be formed on the surface 2t and in the vicinity thereof. The semiconductor layers 3a, 3b, 4a, 4b, 5a, 5b are obtained by introducing impurities into the surface 2t and annealing (see steps F4 and F5). Therefore, the second example in which implantation defects are less likely to be formed on the surface 2t and in the vicinity thereof is more advantageous than the first example from the viewpoint of suppressing the deterioration of the electrical characteristics of the obtained semiconductor device.

In the first example and the second example, the case where there is one position LK where the concentration of recombination centers takes a local maximum has been exemplified. As in the third preferred embodiment, there may be a plurality of positions where the concentration takes a local maximum. For example, when the concentration takes a local maximum at two different positions in the direction Z, the particles H can be implanted by the method of the second example in order to introduce recombination centers so that the concentration takes a local maximum at a position closer to the surface 2s side, and the particles H can be implanted by the method of the first example in order to introduce recombination centers so that the concentration takes a local maximum at a position closer to the surface 2t side. Varying the method of implanting the particles H in this manner is advantageous from the viewpoint of improving the precision of the positions where recombination centers are formed.

### 12. Modification of Concentration Distribution

### <12-1. First Modification of Concentration Distribution>

In the semiconductor layer 2, when the concentration Cr takes local maxima at a plurality of positions in the direction Z, the concentration Cr does not take local maxima but takes local minima between adjacent positions among the respective positions. The interval between the positions may be narrow, and for example, the concentration Cr between the positions may be larger than the value Cd. It can also be said that the concentration Cr distributed in a multimodal manner in such a state has hems overlapping each other between adjacent peaks.

### <12-2. Second Modification of Concentration Distribution>

The distance Dp or the distances Dp1, Dp2, . . . at which the concentration Cr takes local maxima may be deviated from the positions satisfying the above formulae in the direction Z or may be deviated by 1 μm or less, for example, in addition to the cases of satisfying the above formulae.

### 13. General Description of Present Disclosure

A general description of the above embodiments and examples will be given below.

### <13-1. General Description of Concentration Distribution>

Each of the semiconductor devices 100, 100A, 100B, 101, 102, 103, 104, 200, 200A, 200B, 200C, 200D, 500, 600, 700 includes the semiconductor layers 2, 3a.

The semiconductor layer 2 has the surfaces 2s, 2t. In the direction Z, the surface 2t faces the surface 2s. The conductivity type of the semiconductor layer 2 is, for example, n-type.

The semiconductor layer 3a is adjacent to the surface 2t. The conductivity type of the semiconductor layer 3a is opposite to the conductivity type of the semiconductor layer 2, and is, for example, p-type.

The semiconductor layer 2 contains recombination centers at the concentration Cr. In the distributions Q0, Q1, . . . , and Q6 of the concentration Cr in the direction Z, the local maxima Cp, Cp1, Cp2, . . . appear at at least one position (distances Dp, Dp1, Dp2, . . . ) between the surface 2s and the surface 2t and away from either of the surfaces 2s, 2t.

According to the semiconductor devices 100, 100A, 500, 600, in the distribution Q0, the local maximum Cp of the concentration Cr appears at the position LK which is at the distance Dp (see FIGS. 3, 10, 14, and 15).

According to the semiconductor device 101, in the distribution Q1, the local maxima Cp1 and Cp2 of the concentration Cr appear at the positions LK1 and LK2 which are respectively at the distances Dp1 and Dp2 (see FIG. 4).

According to the semiconductor device 102, in the distribution Q2, the local maxima Cp1, Cp2, and Cp3 of the concentration Cr appear at the positions LK1, LK2, and LK3 which are respectively at the distances Dp1, Dp2, and Dp3 (see FIG. 5).

According to the semiconductor device 103, in the distribution Q3, the local maxima Cp1 and Cp2 of the concentration Cr appear at the positions LK1 and LK2 which are respectively at the distances Dp1 and Dp2 (see FIG. 6).

According to the semiconductor device 104, in the distribution Q4, the local maxima Cp1, Cp2, and Cp3 of the concentration Cr appear at the positions LK1, LK2, and LK3 which are respectively at the distances Dp1, Dp2, and Dp3 (see FIG. 7).

According to the semiconductor devices 200, 200A, 200B, 200C, in the distribution Q5, the local maximum Cp of the concentration Cr appears at the position LK which is at the distance Dp (see FIGS. 9, 11, 12, and 13).

According to the semiconductor device 700, in the distribution Q6, the local maximum Cp of the concentration Cr appears at the position LK which is at the distance Dp (see FIG. 16).

In the distributions Q1, Q2, Q3, and Q4 of the concentration Cr, the local maxima Cp1, Cp2, . . . appear at a plurality of positions (distances Dp1, Dp2, . . . ) in the direction Z.

According to the semiconductor devices 101, 103, in the distributions Q1 and Q3, respectively, the local maxima Cp1 and Cp2 of the concentration Cr appear at the positions LK1 and LK2 which are respectively at the distances Dp1 and Dp2 (see FIGS. 4 and 6).

According to the semiconductor devices 102, 104, in the distributions Q2 and Q4, respectively, the local maxima Cp1, Cp2, and Cp3 of the concentration Cr appear at the positions LK1, LK2 and LK3 which are respectively at the distances Dp1, Dp2 and Dp3 (see FIGS. 5 and 7).

In the semiconductor layer 2, the local maxima Cp1 and Cp2 appear in the distributions Q1, Q2, Q3, and Q4 at equal intervals in the direction Z (see formulae (4), (5), (6), (8), (10), (11), and (13)).

In the distribution Q2, the local maximum Cp3 also appears on the surface 2s (see FIG. 5).

### <13-2. General Description of Insulated Gate Transistor>

Each of the semiconductor devices 100, 100A, 100B, 101, 102, 103, 104, 200, 200A, 200B, 200C, 200D, 500, 600 includes the semiconductor layer 5a, a first insulating layer, and a first conductive layer.

The semiconductor layer 5a is adjacent to the semiconductor layer 3a from the side opposite to the semiconductor layer 2. The conductivity type of the semiconductor layer 5a is the same as the conductivity type of the semiconductor layer 2, and is, for example, n-type.

According to the semiconductor devices 100, 101, 102, 103, 104, 100A, 100B, 500, 600, the insulating layer 6a corresponds to the first insulating layer. According to the semiconductor devices 200, 200A, 200B, 200C, 200D, the insulating layer 6t corresponds to the first insulating layer. The insulating layer 6a and the insulating layer 6t are common from the viewpoint of reaching the semiconductor layer 5a from the semiconductor layer 2 across the semiconductor layer 3a while being adjacent to the semiconductor layers 2, 3a, 5a.

According to the semiconductor devices 100, 101, 102, 103, 104, 100A, 100B, 500, 600, the conductive layer 7a corresponds to the first conductive layer. According to the semiconductor devices 200, 200A, 200B, 200C, 200D, the conductive layer 7t corresponds to the first conductive layer. The conductive layer 7a and the conductive layer 7t are common from the viewpoint of facing the semiconductor layer 3a with the first insulating layer interposed therebetween.

The insulating layer 6a and the conductive layer 7a form the planar insulated gate, and the insulating layer 6t and the conductive layer 7t form the trench-type insulated gate TG.

The semiconductor devices 100, 101, 102, 103, 104, 100A, 100B, 500, 600 each have the planar insulated gate. For example, all the local maxima of the distributions Q0, Q1, Q2, Q3, and Q4 of the concentration Cr appear on the surface 2s side relative to the insulating layer 6a (see FIGS. 2 to 7, 10, 14, and 15). For example, the local maximum Cp appears in the distribution Q0 at the center (distance Dp) in the direction Z between the semiconductor layer 3a and the surface 2s (see FIGS. 3, 10, and 14, and the formula (2)).

The semiconductor devices 200, 200A, 200B, 200C, 200D each have the trench-type insulated gate TG. For example, all the local maxima Cp of the distribution Q5 of the concentration Cr appear on the surface 2s side relative to the insulating layer 6t (see FIGS. 8, 9, and 11 to 13). For example, the local maximum Cp appears in the distribution Q5 at the center (distance Dp) in the direction Z between the end on the surface 2s side of the insulating layer 6t and the surface 2s (see the formula (10)).

### <13-3. General Description of Termination Region>

For example, the termination structure 22 is provided in the termination region R2. The semiconductor layer 3b is adjacent to the surface 2t. The conductivity type of the semiconductor layer 3b is opposite to the conductivity type of the semiconductor layer 2, and is, for example, p-type. The termination structure 22 is adjacent to the surface 2t and arranged side by side with the semiconductor layer 3b on the side opposite to the semiconductor layer 5a (see FIGS. 2, 8, and 21 to 23).

The concentration of recombination centers of the semiconductor layer 2 between the termination structure 22 and the surface 2s is lower than the local maximum of recombination centers. For example, the position LK has the end LKB in the termination region R2, and the termination structure 22 is located on the side opposite to the position LK relative to the end LKB in plan view (see FIGS. 21 to 23).

### <13-4. General Description of Schottky Junction>

The semiconductor device 500 includes the electrode 15b which is adjacent to both of the semiconductor layers 3a, 28 (see FIG. 14). The semiconductor layer 28 can also be regarded as a part of the semiconductor layer 2.

The semiconductor device 700 includes the electrode 15a which is adjacent to both of the semiconductor layers 17, 29 (see FIG. 16). The semiconductor layer 17 is adjacent to the surface 2t similarly to the semiconductor layer 3a. The conductivity type of the semiconductor layer 17 is the same as the conductivity type of the semiconductor layer 3a, and is, for example, p-type. The semiconductor layer 29 can also be regarded as a part of the semiconductor layer 2.

The electrode 15a and the electrode 15b are common from the viewpoint of adopting a material for realizing a Schottky junction with a part of the semiconductor layer 2. The semiconductor layer 3a and the semiconductor layer 17 are common from the viewpoint of having a conductivity type opposite to the conductivity type of the semiconductor layer 2.

Note that the preferred embodiments can be freely combined and each of the preferred embodiments can be modified or omitted as appropriate.

Aspects of the present disclosure are collectively described below as appendices.

### APPENDIX 1

A semiconductor device comprising:
a first semiconductor layer that has a first surface and a second surface facing the first surface in a first direction, contains recombination centers, and has a first conductivity type; and
a second semiconductor layer that is adjacent to the second surface and has a second conductivity type which is opposite to the first conductivity type, wherein
local maxima appear in a distribution of a concentration of the recombination centers in the first direction at at least one position between the first surface and the second surface and away from either of the first surface and the second surface.

### APPENDIX 2

The semiconductor device according to Appendix 1, wherein the local maxima appear in the distribution at a plurality of positions in the first direction.

### APPENDIX 3

The semiconductor device according to Appendix 2, wherein the local maxima appear in the distribution at equal intervals in the first direction in the first semiconductor layer.

### APPENDIX 4

The semiconductor device according to any one of Appendices 1 to 3, wherein the local maxima also appear in the distribution on the first surface.

### APPENDIX 5

The semiconductor device according to any one of Appendices 1 to 4, further comprising:
a third semiconductor layer that is adjacent to the second semiconductor layer from a side opposite to the first semiconductor layer and has the first conductivity type;
a first insulating layer that is adjacent to the first semiconductor layer, the second semiconductor layer, and the third semiconductor layer and reaches the third semiconductor layer from the first semiconductor layer across the second semiconductor layer; and
a first conductive layer that faces the second semiconductor layer with the first insulating layer interposed therebetween, wherein
all of the local maxima of the distribution appear closer to the first surface than the first insulating layer.

### APPENDIX 6

The semiconductor device according to Appendix 5, wherein the local maxima appear in the distribution at a center in the first direction between the second semiconductor layer and the first surface.

### APPENDIX 7

The semiconductor device according to Appendix 5, wherein the local maxima appear in the distribution at a center in the first direction between the first surface and an end of the first insulating layer on a side of the first surface.

### APPENDIX 8

The semiconductor device according to any one of Appendices 5 to 7, further comprising:
a fourth semiconductor layer that is adjacent to the second surface and has the second conductivity type; and
a termination structure that is adjacent to the second surface and is arranged side by side with the fourth semiconductor layer on a side opposite to the third semiconductor layer, wherein
a concentration of the recombination centers of the first semiconductor layer between the termination structure and the first surface is lower than the local maxima.

### APPENDIX 9

The semiconductor device according to any one of Appendices 1 to 4, further comprising:
an electrode that is adjacent to both the second semiconductor layer and the first semiconductor layer, wherein
a material that achieves a Schottky junction with the second semiconductor layer is adopted for the electrode.

### APPENDIX 10

The semiconductor device according to any one of Appendices 1 to 9, further comprising:
a fifth semiconductor layer that is adjacent to the first semiconductor layer on the first surface and has the first conductivity type, wherein
an impurity concentration of the fifth semiconductor layer is 1×10¹⁸ cm⁻³ or more and 1×10¹⁹ cm⁻³ or less, and
a maximum value of an impurity concentration of the first semiconductor layer is less than 1×10¹⁸ cm⁻³.

### APPENDIX 11

The semiconductor device according to Appendix 10, wherein the local maxima appear in the distribution in the fifth semiconductor layer.

### APPENDIX 12

The semiconductor device according to any one of Appendices 1 to 9, further comprising:
a fifth semiconductor layer that is adjacent to the first semiconductor layer on the first surface and has the second conductivity type.

### APPENDIX 13

The semiconductor device according to any one of Appendices 1 to 12, further comprising:
a sixth semiconductor layer that is adjacent to the second semiconductor layer, extends toward the first surface, and has the second conductivity type.

### APPENDIX 14

A method of manufacturing the semiconductor device according to any one of Appendices 1 to 13, wherein
protons or helium is implanted into the first semiconductor layer in a direction from the first surface toward the second surface.

While the disclosure has been shown and described in detail, the foregoing description is in all aspects illustrative and not restrictive. It is therefore understood that numerous modifications and variations can be devised.

What is claimed is:

1. A semiconductor device comprising:
a first semiconductor layer that has a first surface and a second surface facing the first surface in a first direction, contains recombination centers, and has a first conductivity type; and
a second semiconductor layer that is adjacent to the second surface and has a second conductivity type which is opposite to the first conductivity type, wherein
local maxima appear in a distribution of a concentration of the recombination centers in the first direction at at least one position between the first surface and the second surface and away from either of the first surface and the second surface.

2. The semiconductor device according to claim 1, wherein the local maxima appear in the distribution at a plurality of positions in the first direction.

3. The semiconductor device according to claim 2, wherein the local maxima appear in the distribution at equal intervals in the first direction in the first semiconductor layer.

4. The semiconductor device according to claim 1, wherein the local maxima also appear in the distribution on the first surface.

5. The semiconductor device according to claim 1, further comprising:
a third semiconductor layer that is adjacent to the second semiconductor layer from a side opposite to the first semiconductor layer and has the first conductivity type;
a first insulating layer that is adjacent to the first semiconductor layer, the second semiconductor layer, and the third semiconductor layer and reaches the third semiconductor layer from the first semiconductor layer across the second semiconductor layer; and
a first conductive layer that faces the second semiconductor layer with the first insulating layer interposed therebetween, wherein
all of the local maxima of the distribution appear closer to the first surface than the first insulating layer.

6. The semiconductor device according to claim 5, wherein the local maxima appear in the distribution at a center in the first direction between the second semiconductor layer and the first surface.

7. The semiconductor device according to claim 5, wherein the local maxima appear in the distribution at a center in the first direction between the first surface and an end of the first insulating layer on a side of the first surface.

8. The semiconductor device according to claim 5, further comprising:
a fourth semiconductor layer that is adjacent to the second surface and has the second conductivity type; and
a termination structure that is adjacent to the second surface and is arranged side by side with the fourth semiconductor layer on a side opposite to the third semiconductor layer, wherein
a concentration of the recombination centers of the first semiconductor layer between the termination structure and the first surface is lower than the local maxima.

9. The semiconductor device according to claim 1, further comprising:
an electrode that is adjacent to both the second semiconductor layer and the first semiconductor layer, wherein
a material that achieves a Schottky junction with the second semiconductor layer is adopted for the electrode.

10. The semiconductor device according to claim 1, further comprising:
a fifth semiconductor layer that is adjacent to the first semiconductor layer on the first surface and has the first conductivity type, wherein
an impurity concentration of the fifth semiconductor layer is 1×10¹⁸ cm⁻³ or more and 1×10¹⁹ cm⁻³ or less, and
a maximum value of an impurity concentration of the first semiconductor layer is less than 1×10¹⁸ cm⁻³.

11. The semiconductor device according to claim 10, wherein the local maxima appear in the distribution in the fifth semiconductor layer.

12. The semiconductor device according to claim 1, further comprising:
a fifth semiconductor layer that is adjacent to the first semiconductor layer on the first surface and has the second conductivity type.

13. The semiconductor device according to claim 1, further comprising:
a sixth semiconductor layer that is adjacent to the second semiconductor layer, extends toward the first surface, and has the second conductivity type.

14. A method of manufacturing the semiconductor device according to claim 1, wherein
protons or helium is implanted into the first semiconductor layer in a direction from the first surface toward the second surface.
